(19) United States
(12) Patent Application Publication
(10) Pub. No.: US 2022/0159878 A1
(43) Pub. Date: May 19, 2022

(54) INPUT/OUTPUT CONNECTOR WITH HEAT SINK

(71) Applicant: Molex, LLC, Lisle, IL (US)

(72) Inventors: Robert DILLMAN, Santa Clara, CA (US); Christopher L. KAPUSCINSKI, Mount Prospect, IL (US)

(73) Assignee: Molex, LLC, Lisle, IL (US)

(21) Appl. No.: 17/435,708

(22) PCT Filed: Mar. 19, 2020
(86) PCT No.: PCT/US2020/023465

§ 371 Date: Sep. 2, 2021

Related U.S. Application Data
(60) Provisional application No. 62/820,608, filed on Mar. 19, 2019.
(60) Provisional application No. 62/826,009, filed on Mar. 29, 2019.

(51) Int. Cl. H05K 7/20; H05K 1/18; H01R 13/6581

(52) U.S. Cl. CPC H05K 7/20509; H05K 1/18; H01R 13/6581; H05K 2201/10371; H05K 2201/066; H05K 2201/10189; H05K 2201/09063

(57) ABSTRACT

A card has a rear portion with contact pads provided therein and has an input/output (I/O) connector assembly mounted on a first side with the I/O connector assembly including a receptacle connector positioned in a cage. A heat sink assembly is mounted on the cage and is configured to extend into the cage so as to help cool an inserted plug module. If desired a second heat sink can be mounted on a second side of the card. The second heat sink can extend through an aperture in the card into a port defined by the I/O connector assembly so that a module inserted into the port can be cooled from two sides. The card can be configured to be mounted

### RELATED APPLICATIONS

This application claims priority to U.S. Provisional Appln. Ser. No. 62/820,608, filed Mar. 19, 2019, and to U.S. Provisional Appln. Ser. No. 62/826,009, filed Mar. 29, 2019.

### TECHNICAL FIELD

This disclosure relates to the field of input/output (I/O) connectors, more specifically to I/O connectors suitable for use in high data rate applications.

### DESCRIPTION OF RELATED ART

Input/output (I/O) connectors are commonly used to provide transmission of signals between two devices. Increasingly I/O connectors are being used to support data rates and distances that make the use of passive cables assemblies unfeasible from a theoretical standpoint. As a result, many such cable assemblies are being provided as optical cables.

Optical cables, while more expensive, allow a system to be set up that can provide high data rates over long distances. For example, 100 Gb can be supported over a quad small form factor pluggable (QSFP) connector system at distances of 100 meters (or more), a distance that would be impossible for a passive cable to support. One issue with using optical cables, however, is that the thermal energy emitted by the transceiver makes it difficult to pack a number of ports in a single box or chassis. As a result, certain individuals would appreciate a design that could help improve how the thermal energy was managed.

Connectors have been known to provide a riding heat sink to help provide cooling, such as is disclosed in U.S. Pat. No. 6,749,448. Attempts to improve on this design have had some success but often the improvements are either too expensive or provide less effective cooling, such as the design disclosed by CN UM 206789813. Thus, certain individuals would appreciate additional improvements in cooling technology.

### SUMMARY

A card assembly, which includes a card that can be a conventional circuit board with contact pads provided on one edge, is provided that has a input/output (I/O) connector assembly mounted on it and the card assembly can be configured to have a heat sink assembly on two opposing sides of the card. In an embodiment, one of the heat sinks extends through the card. The card can be configured to be mounted vertically or horizontally.

In one embodiment a card with I/O connector assemblies that define ports is mounted in a vertical orientation. A heat sink assembly can be provided on both sides of the card. The heat sink assembly on both sides can be configured to be a riding heat sink and both heat sink assemblies can extend into the respective port such that an inserted plug module can be cooled from both sides. In an embodiment, one of the heat sink assemblies extends through one or more apertures in the card.

In another embodiment a card with an I/O connector assembly that defines two stacked ports is mounted on the card and the card is arranged in a horizontal direction A heat sink assembly can be provided on both sides of the card. Both of the heat sink assemblies can be a riding heat sink and can extend into the respective ports such that an inserted plug module can be cooled regardless of whether it is inserted in the top or bottom port sides. In an embodiment, one of the heat sink assemblies extends through the card. An internal heat sink

In another embodiment, a card with an I/O connector assembly that defines a port is mounted thereon is configured in a horizontal direction. A heat sink assembly can be provided on both sides of the card. The heat sink assemblies can be configured as a riding heat sink and can extend into the port from two opposing sides such that an inserted plug module can be cooled from both sides. In an embodiment, one of the heat sinks extends through the card.

### BRIEF DESCRIPTION OF THE DRAWINGS

The present application is illustrated by way of example and not limited in the accompanying figures in which like reference numerals indicate similar elements and in which:

FIG. 1 illustrates a perspective view of an embodiment of a box with the sides of the box removed.

FIG. 2 illustrates a perspective view of an embodiment of a I/O cage assembly.

FIG. 2A illustrates a perspective view of an embodiment of a heat sink.

FIG. 3 illustrates a perspective view an embodiment of a front face of a box.

FIG. 4 illustrates a perspective view of internal features of a box.

FIG. 5 illustrates a perspective view of features of a front face that can be used in a box.

FIG. 6 illustrates a perspective view of a plurality of card assemblies.

FIG. 7 illustrates a perspective view of a card assembly.

FIG. 8 illustrates another perspective view of the card assembly depicted in FIG. 7.

FIG. 9 illustrates a perspective view of another embodiment of a card assembly.

FIG. 10 illustrates a simplified perspective view of the embodiment depicted in FIG. 9.

FIG. 11 illustrates a perspective view of an embodiment of card assemblies connected to a circuit board.

FIG. 12 illustrates a perspective view of card assemblies arranged in a box system that includes a cable tray.

FIG. 13 illustrates a perspective view of a plurality of card assemblies mounted to a circuit board.

FIG. 14 illustrates another perspective view of the embodiment depicted in FIG. 13.

FIG. 15 illustrates another perspective view of the embodiment depicted in FIG. 13.

FIG. 16 illustrates a simplified perspective view of the embodiment depicted in FIG. 13.

FIG. 17 illustrates an elevated side view of a port of the I/O connector assembly.

FIG. 18 illustrates a partially exploded perspective view of the card assembly in the embodiment depicted in FIG. 16.

FIG. 19 illustrates an exploded perspective view of the card assembly depicted in FIG. 16 with the card removed.

FIG. 20 illustrates a simplified perspective view of the embodiment depicted in FIG. 18.

FIG. 21 illustrates a simplified perspective view of the embodiment depicted in FIG. 16 with the cage and heat sinks removed.

FIG. 22 illustrates another perspective view of the embodiment depicted in FIG. 21.

FIG. 23 illustrates a simplified perspective view of the embodiment depicted in FIG. 22.

FIG. 24 illustrates another perspective view of the embodiment depicted in FIG. 23.

FIG. 25 illustrates an elevated side view of the embodiment depicted in FIG. 23.

FIG. 26A illustrates a perspective view of another embodiment of a plurality of card assembly supported by a support member.

FIG. 26B illustrates a simplified perspective view of the embodiment depicted in FIG. 26A.

FIG. 26C illustrates a perspective view of a cross section taken along line 26C-26C in FIG. 26B.

FIG. 26D illustrates an elevated rear view of the embodiment depicted in FIG. 26B.

FIG. 26E illustrates a simplified partially exploded perspective view of the embodiment depicted in FIG. 26B.

FIG. 26F illustrates a partially exploded perspective view of the embodiment depicted in FIG. 26B.

FIG. 26G illustrates a perspective vie of an embodiment of a support member suitable for use in the embodiment depicted in FIG. 26B.

FIG. 26H illustrates another perspective view of the embodiment depicted in FIG. 26G.

FIG. 27A illustrates a schematic representation of a box with a horizontal aligned card assembly.

FIG. 27B illustrates a schematic representation of a card suitable for use in the embodiment depicted in FIG. 27A.

FIG. 28 illustrates a perspective view of an embodiment of a card assembly

FIG. 29 illustrates another perspective view of the embodiment depicted in FIG. 28.

FIG. 30 illustrates a perspective view of another embodiment of a card assembly showing a single cage mounted on the card.

FIG. 31 illustrates a perspective view of a cross section of FIG. 30, taken along line 31-31.

FIG. 32 illustrates a perspective view of a cross section of FIG. 30, taken along line 32-32.

FIG. 33 illustrates a perspective exploded view of the embodiment depicted in FIG. 30.

FIG. 34 illustrates a perspective view of an embodiment of a card assembly.

FIG. 35 illustrates a perspective exploded view of the embodiment depicted in FIG. 34.

FIG. 36 illustrates a perspective view of a cross section of FIG. 34, taken along line 36-36.

FIG. 37 illustrates a perspective view of a cross section of FIG. 34, taken along line 37-37.

### DETAILED DESCRIPTION

The detailed description that follows describes exemplary embodiments and the features disclosed are not intended to be limited to the expressly disclosed combination(s). Therefore, unless otherwise noted, features disclosed herein may be combined together to form additional combinations that were not otherwise shown for purposes of brevity.

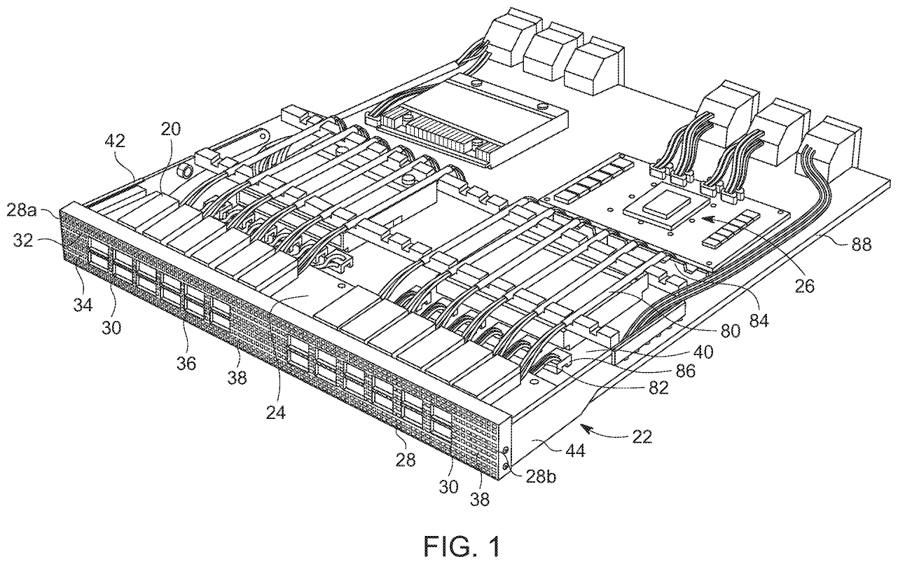

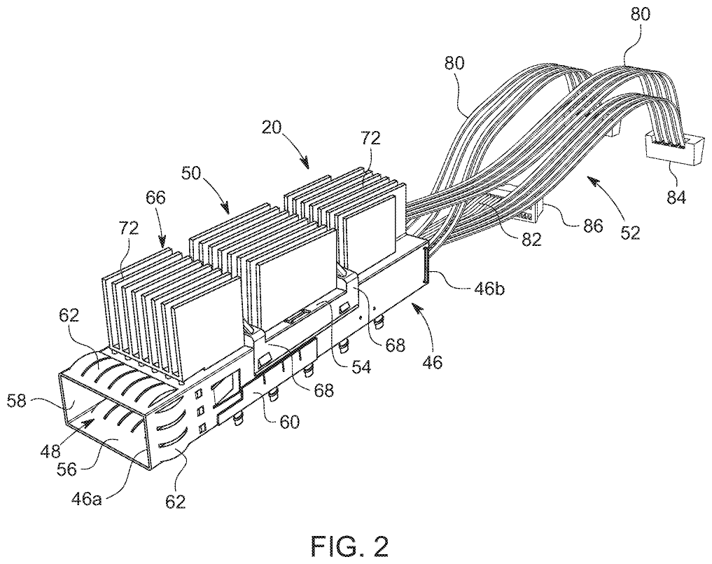

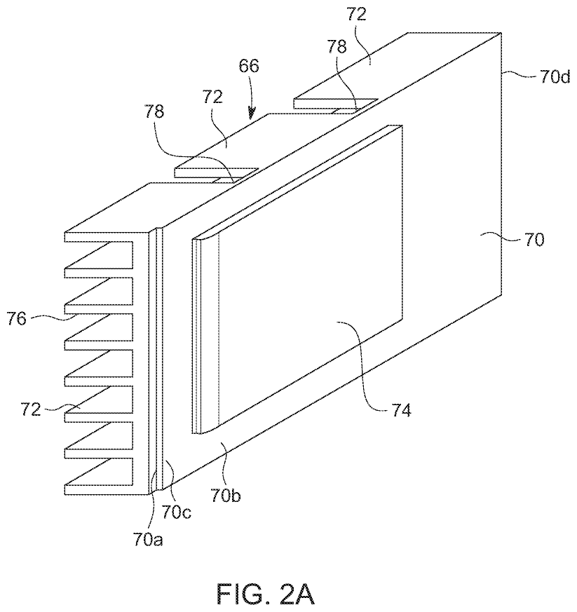

FIGS. 1-2A depict an embodiment of a plurality of input/output (I/O) connector assemblies 20 housed in a box 22 which provides for useful thermal dissipation. The I/O connector assemblies 20 are mounted on and electrically coupled to a front circuit board 24 which is horizontally mounted in the box 22. The front circuit board 24 is positioned between stacked pairs of the I/O connector assemblies 20. The connector assemblies 20 are coupled to a first rear circuit board ²⁶ that supports a chip package in a bypass arrangement for transmitting high speed signals from the I/O connector assemblies 20 to the rear circuit board 26. The connector assemblies 20 are also coupled to a second rear circuit board (not shown) for transmitting low speed signals from the I/O connector assemblies 20 thereto. Plug modules (not shown) are mounted in the I/O connector assemblies 20. The plug modules may be Quad Small Form Factor (QSFP) transceiver modules or any other desired transceiver module (such as, without limitation, SFP, CXP, etc.). High speed signals from the plug modules are routed via the I/O connector assemblies 20 to the rear circuit board 26. Low speed signals and power may be routed through the front circuit board 24, or may be routed using a cable, to the second rear circuit board. The embodiment shown in FIGS. 1 and 2 works well for situations where there is a certain level of thermal load, but such a design tends to be marginal when attempting to cool plug modules that output 8-10 (or more) watts. In addition, the front circuit board 24 may be difficult to package in certain circumstances.

The box 22 has a front wall 28 having a plurality of pairs of stacked openings 30 provided therethrough formed in rows and columns. Each opening 30 extends horizontally relative to side edges 28a, 28b of the front wall 28. As such, a top row 32 of spaced apart openings 30 is provided, and a bottom row 34 of spaced apart openings 30 is provided, which are spaced apart from each other by a section 36 of the front wall 28. As shown, the openings 30 form two sets of 2×6 matrices, however, this is an example embodiment, and the numbers of openings 30 may vary from this configuration. The front wall 28 has a plurality of air flow openings 38 provided therethrough which allow air to flow through the front wall 28 to cool the I/O connector assemblies 20 mounted therein. Thus, the front wall 28 can be configured to decrease air resistance so as to allow for more air to flow through the box 22 for a given air pressure gradient.

The box 22 is shown with most of the walls removed for purposes of illustration but typically would include a bottom wall 88, as well as side, rear and top walls (not shown). A frame can be positioned in the box and can like side walls 42, 44 that extend rearwardly from the front wall 28 where the frame can help support circuit boards that are positioned in the box 22.

The front circuit board 24 is mounted in a horizontal orientation and is positioned to extend rearwardly from the section 36 of the front wall 28. As such, the front circuit board 24 is positioned between the top row 32 of openings 30 and the bottom row 34 of openings 30. Pairs of the I/O connector assemblies 20 are mounted belly to belly on the front circuit board 24. As such, a plurality of spaced apart I/O connector assemblies 20 are mounted on a top surface of the front circuit board 24 and a plurality of spaced apart I/O connector assemblies 20 are mounted on a bottom surface of the front circuit board 24.

An example of one of the I/O connector assemblies 20 is shown in FIG. 2. The I/O connector assembly 20 includes a conductive cage 46 having a front end 46a and a rear end 46b and which has a port 48 extending from the front end 46a toward the rear end 46b thereof, a receptacle connector (not shown) mounted in the port 48 of the cage 46, a heat sink assembly 50 mounted to the cage 46, and a cable assembly 52 connected to the receptacle connector.

The cage 46 includes parallel first and second walls 54, 56 and parallel side walls 58, 60 extending between the first and second walls 54, 56 at opposite side edges thereof. Inner surfaces of the walls 54, 56, 58, 60 form the port 48. The second wall 56 does not extend the full length of the cage 46 such that an opening (not shown) is formed proximate to the rear end 46b of the cage 46. The wall 54 of the cage 46 includes an opening (not shown) therethrough which is rearward of the front end 46a of the cage 46. The receptacle connector is inserted into the port 48 through the opening formed by the second wall 56 and terminals (not shown) of the receptacle connector extend from the second wall 56. Spring fingers 62 may be provided on the walls 54, 56, 58, 60 to assist in connecting the cage 46 to the respective opening 30 in the front wall 28. The cage 46 may be formed by stamping and forming. The cage 46 is thermally conductive and forms a shield assembly for the components mounted therein. When the cages 46 are connected to the front wall 28, the front ends 46a of the cages 46 form ports through the front wall 28.

In the embodiment shown in FIGS. 1-2A, the heat sink assembly 50 is formed from a thermally conductive material and includes a heat sink 66 and a clip 68 which attaches the heat sink 66 to the wall 54 to the cage 46. As shown, the heat sink 66 includes a base 70 having a first surface 70a and a planar second, opposite surface 70b which extends from a front end 70c of the base 70 to a rear end 70d of the base 70, a plurality of conductive fins 72 extending outwardly from the first surface 70a, and a projection 74 extending outwardly from the second surface 70b. The projection 74, as shown, may include a chamfer or angled front portion to ensure smoother engaging with an inserted plug module in operation. In an embodiment as shown in the drawings, the fins 72 are elongated and extend from the front end 70c to the rear 70d, such that elongated channels 76 are formed therebetween. As shown, multiple sets of fins 72 may be provided, with the sets of fins 72 being separated by sections 78 of the first surface 70a of the base 70. In an alternative embodiment (not shown), the fins 72 can be formed in an array of pillars or some other desirable fin pattern/construction as desired.

The second surface 70b seats against an outer surface of the wall 54. The projection 74 extends through the opening in the wall 54 of the cage 46 and into the port 48 thereof. The clip 68 attaches to the side walls 158, 160 to attach the heat sink 66 to the wall 54 of the cage 46, and in an embodiment, the clip 68 is seated in the sections 78.

A plug module (not shown) is inserted through the front end 46a of the cage 46, into the port 48 and engages with the receptacle connector in a known manner. The plug module forms a primary electromagnetic containment and the cage 46 forms a conductive sleeve around the plug module. When the plug module is inserted into the cage 46, the plug module engages with the projection 74 and with a card slot of the receptacle connector 90. The clip 68 may allow the base 70 of the heat sink 66 to move away from the wall 54 when the plug module is inserted and engages with the projection 74. To cool the inserted plug module, the projection 74 conducts thermal energy away from the higher temperature plug module toward the fins 72 (that in an embodiment can dissipate heat by convection) to help cool the plug module.

The cable assembly 52 includes a plurality of cables 80 connected to the receptacle connector for transmitting high speed signals from the plug module to the first rear circuit board 26, and plurality of cables 82 connected to the receptacle connector for transmitting low speed signals from the plug module to the second rear circuit board. The cables 80 are terminated with connectors 84 and the cables 82 are terminated with a connector 86.

In the embodiment of FIGS. 1-2A, the I/O connector assemblies 20 in the top row 32 have the wall 56 mounted to the top surface of the front circuit board 24 such that the wall 54 forms a top wall and the fins 72 extend upwardly from the front circuit board 24. The cages 46 in the top row 32 may be mounted to the front circuit board 24 either via a surface-mount technology (SMT) operation or via an interference fit using press-fit tails as is known in the art. The receptacle connectors within the cages 46 of the top row 32 of the I/O connector assemblies 20 electrically connect with the front circuit board 24 to provide a path for the low speed signals and power to pass therethrough. The channels 76 between the fins 72 of the connector assemblies 20 in the top row 32 align with the air flow openings 38 such that air flows through openings 38 and through the channels 76. The I/O connector assemblies 20 in the bottom row 34 have the wall 56 mounted to the bottom surface of the front circuit board 24 such that the wall 54 forms a bottom wall and the fins 72 extend downwardly from the front circuit board 24. The cages 46 in the bottom row 34 may be mounted to the front circuit board 24 either via a surface-mount technology (SMT) operation or via an interference fit using press-fit tails as is known in the art. The receptacle connectors within the cages 46 of the bottom row 34 of the I/O connector assemblies 20 electrically connect with the front circuit board 24 to provide a path for the low speed signals and power to pass therethrough. The channels 76 between the fins 72 of the connector assemblies 20 in the bottom row 34 align with the air flow openings 38 such that air flows through openings 38 and through the channels 76.

The embodiment shown in FIGS. 1-2A will typically require that the plug modules in the top row 32 of ports formed by the I/O connector assemblies 20 have the opposite orientation of the plug modules in the bottom row 34 of ports formed by the I/O connector assemblies 20 so that both I/O connector assemblies can use a standard riding heat sink configuration.

A floor 88 of the box 22 can be used to support the cables 80 as the cables 80 extend from the cages 46 to the rear circuit board 26. Alternatively, a tray can be used. If a tray is used, the tray (which can be rigidly or flexibly connected to the front connector portion) helps route the cables carrying the high speed signals to places adjacent the ASIC/computer chip and can help ensure the cables remain in a desired orientation (which may be desirable if a substantial number of cables are provided).

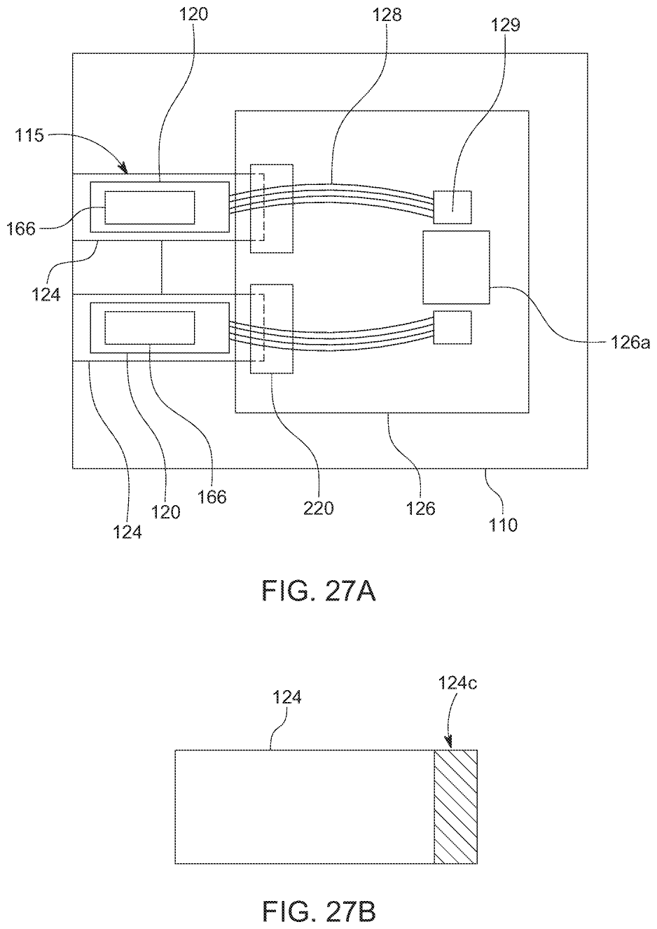

FIGS. 27A, 27B depict a schematic representation of an embodiment of a plurality of card assemblies 115 that include an input/output (I/O) connector assemblies 120 housed in a box 110 (which may be formed like box 22 without the top row 32 of openings 30) which provides enhanced thermal dissipation. Specifically, FIGS. 27a-27B illustrate a schematic representation of a horizontal card construction. In an embodiment where a card assembly 115 is used, a card 124 supports an I/O connector assembly 120 that includes a heat sink 166. A right-angle connector 220 can be provided on a main circuit board 126 and the card 124 can include contact pads 124c on the back edge of the card that is configured to be inserted into the right-angle connector 220. As can be appreciated, the card 124 could also be connected to a main circuit board 126 with cables 128.

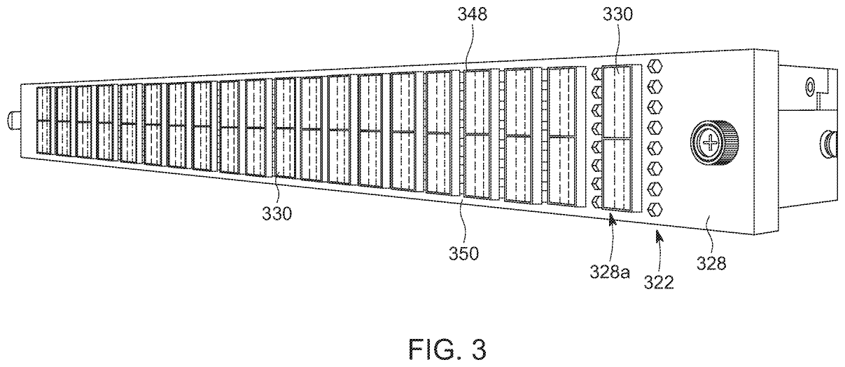

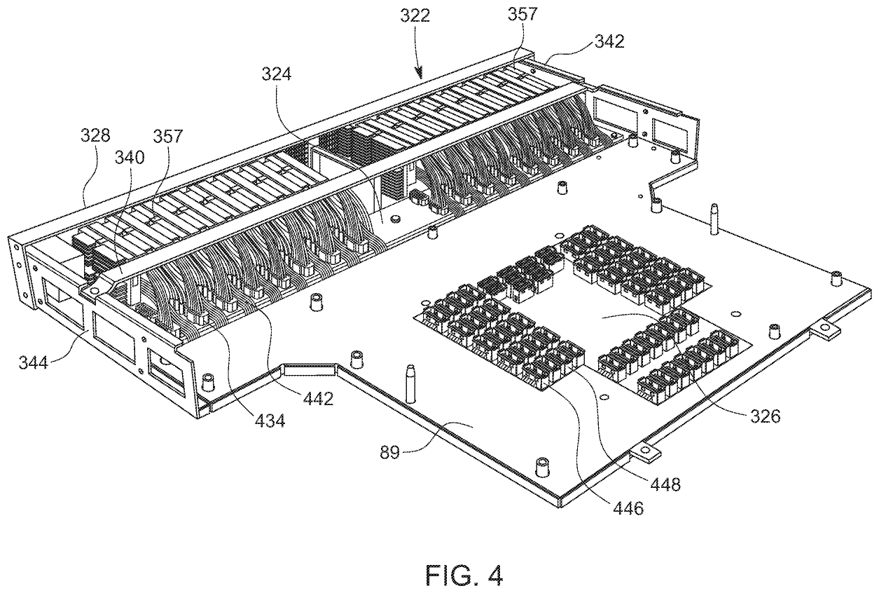

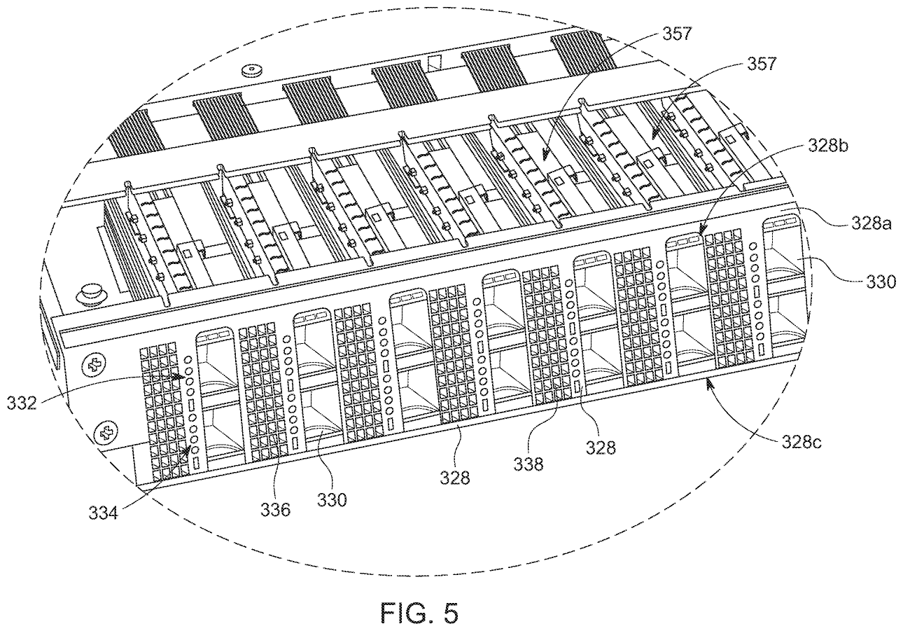

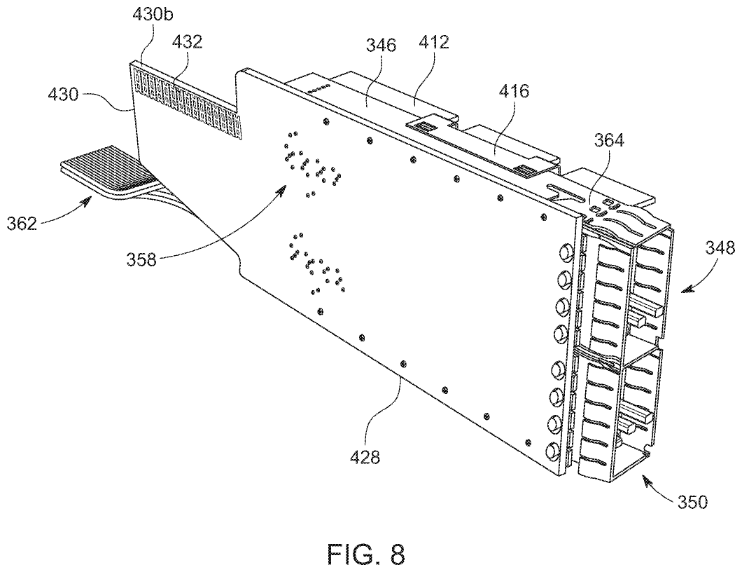

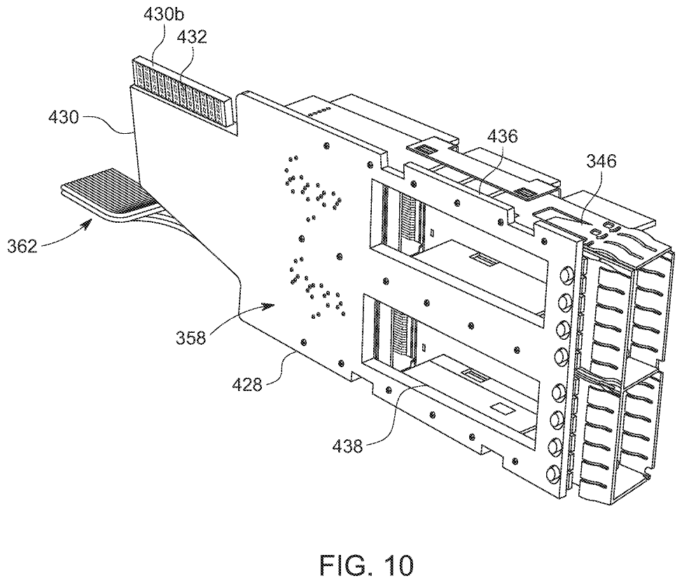

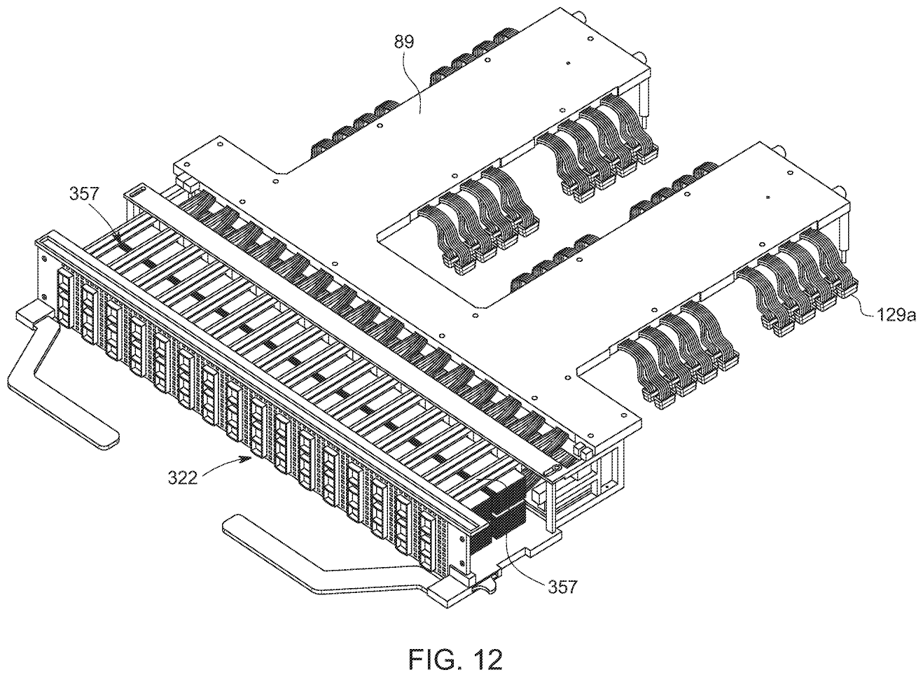

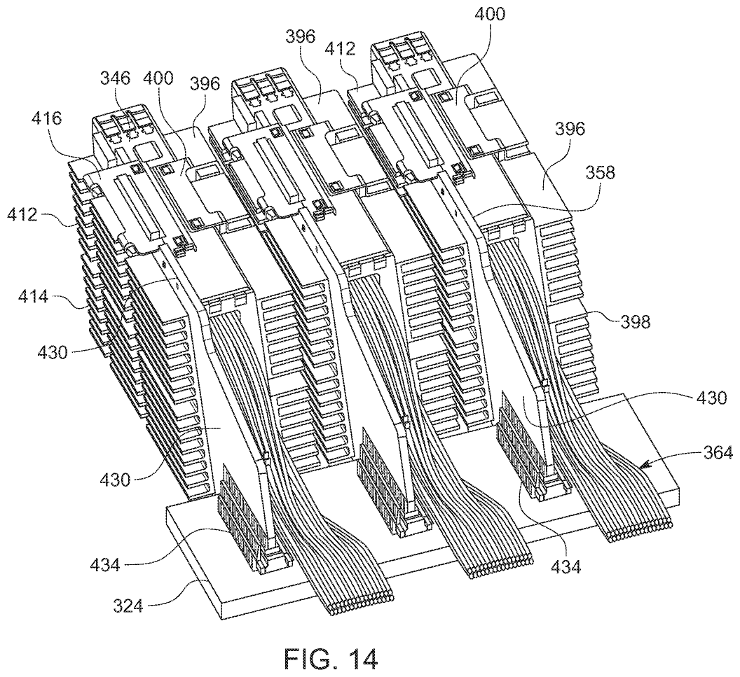

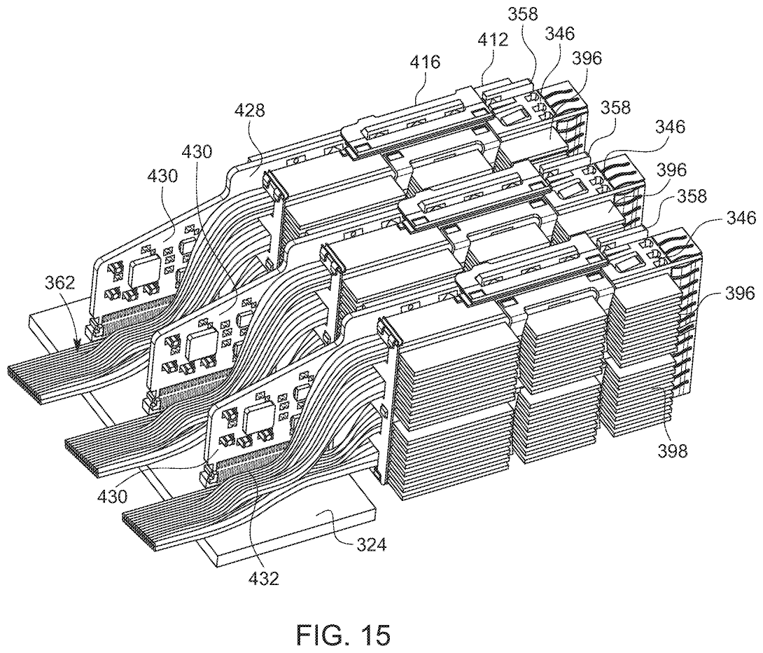

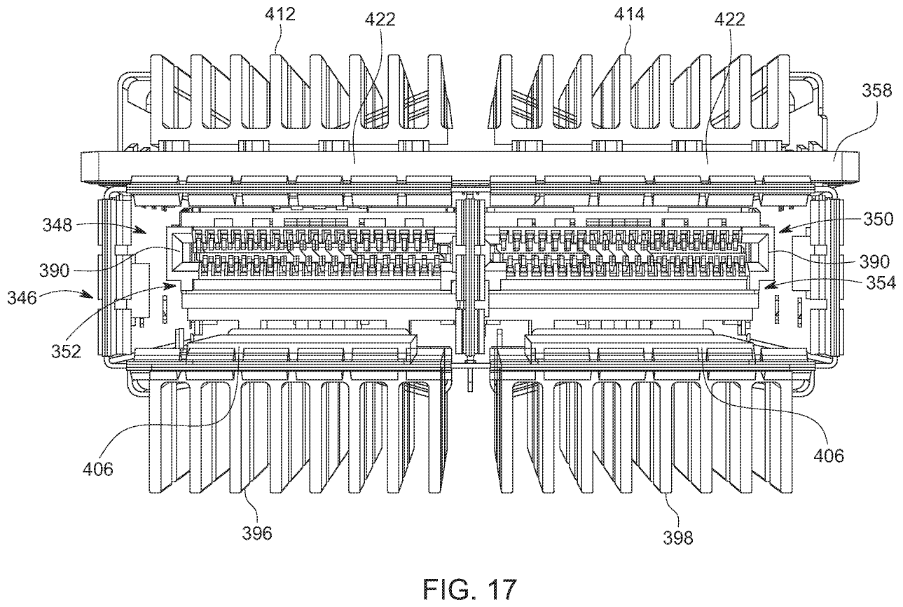

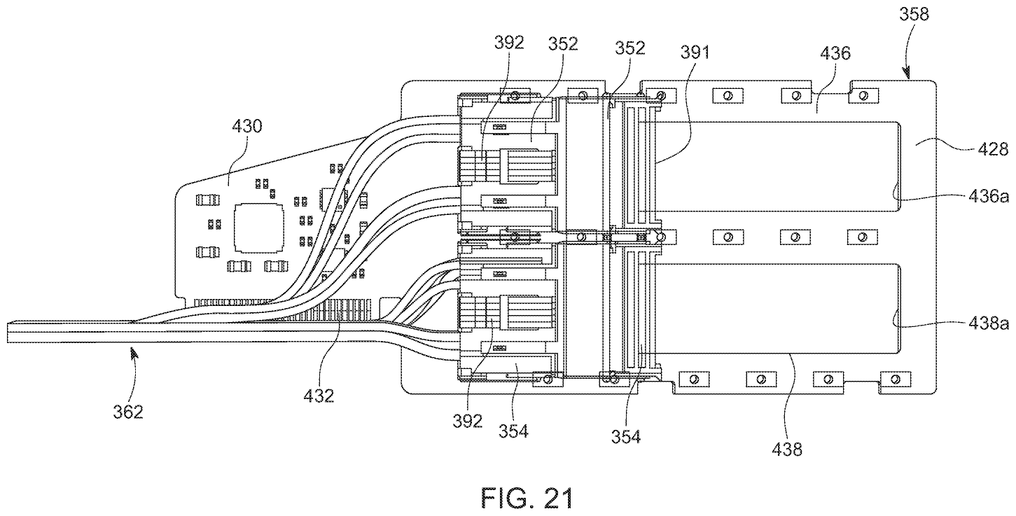

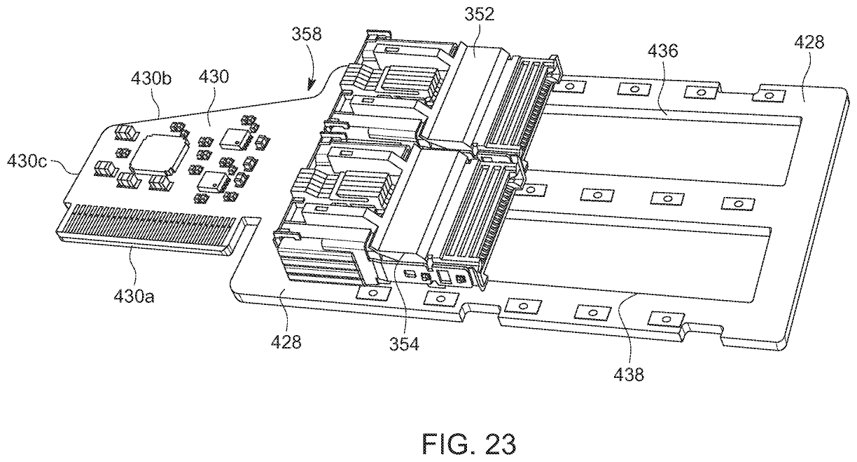

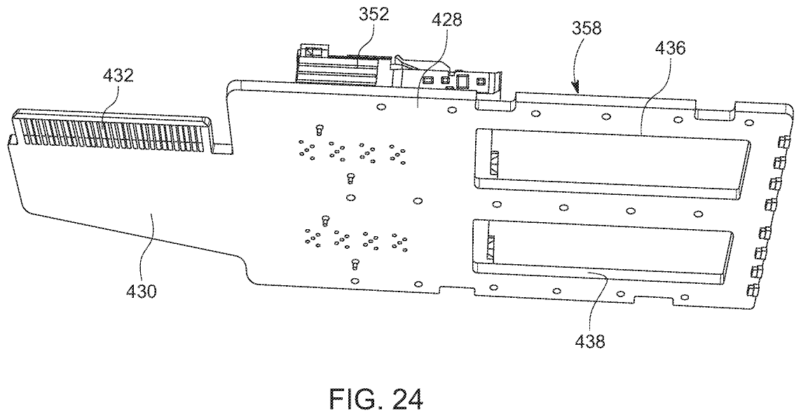

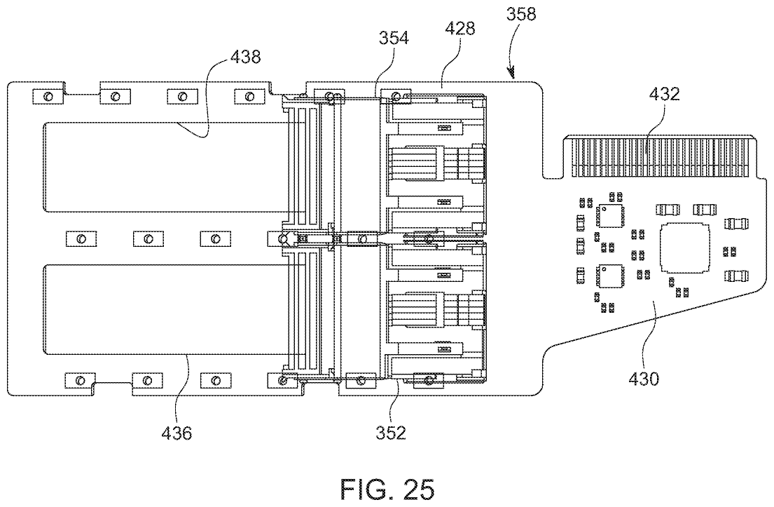

As depicted, the I/O connector assemblies 120 is positioned in the box 110 and positioned in the box is the main circuit board 126 that supports a chip package 126a (which can be any desirable high performance chip). The connector assemblies 120 are coupled to the rear circuit board 126 in a bypass arrangement using cables 128 that are connected to connector system 129 for transmitting high speed signals from the I/O connector assemblies 120 to the chip package 126a in a low loss manner. As discussed above, plug modules (not shown) are mated to the I/O connector assemblies 120. The plug modules may be Quad Small Form Factor (QSFP) transceiver modules or any other desirable format such as QSFP-DD, SFP, CXP, OSFP, etc. It should be noted that other embodiments (such as those depicted in FIGS. 3-25) are also intended to have the cables extending from the respective I/O connector assembly connect to a connector system that is adjacent a chip package configured to receive and/or transmit high speed signals

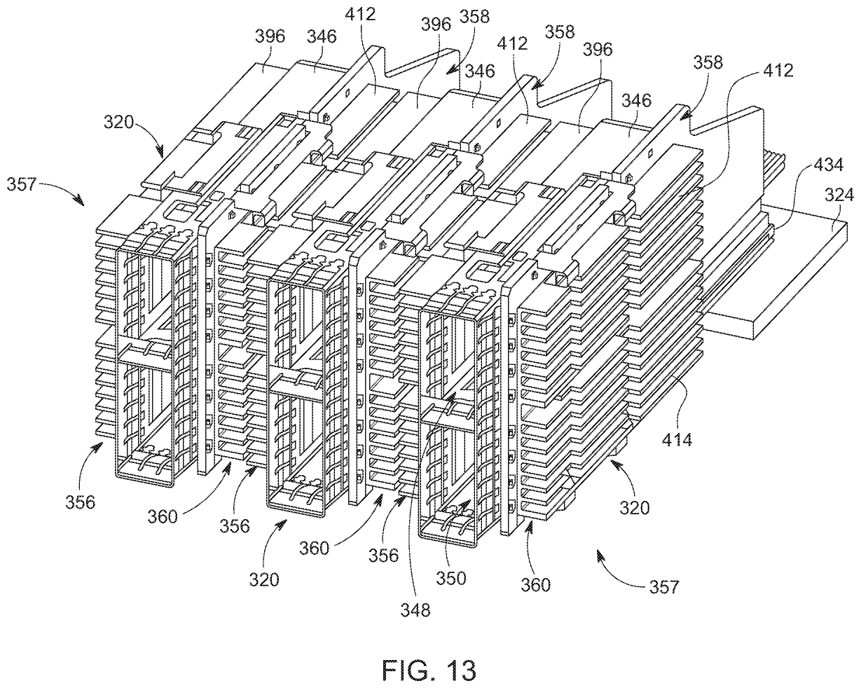

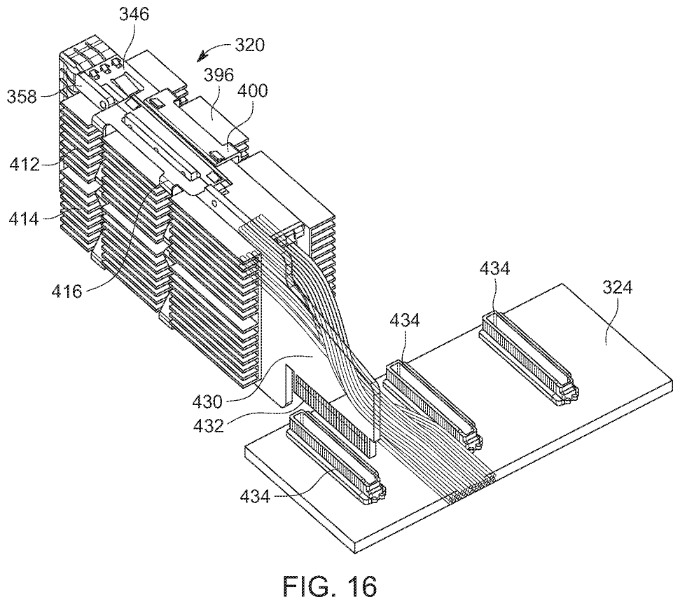

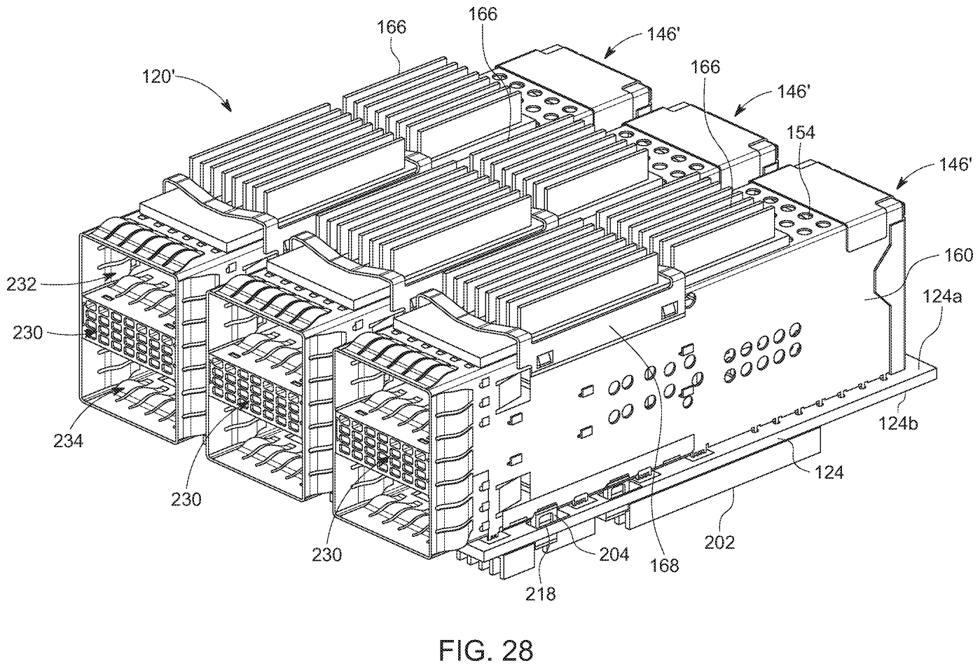

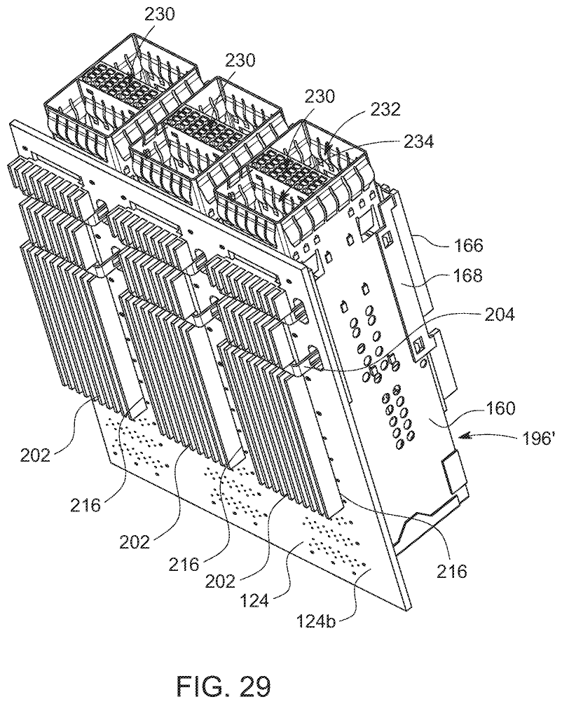

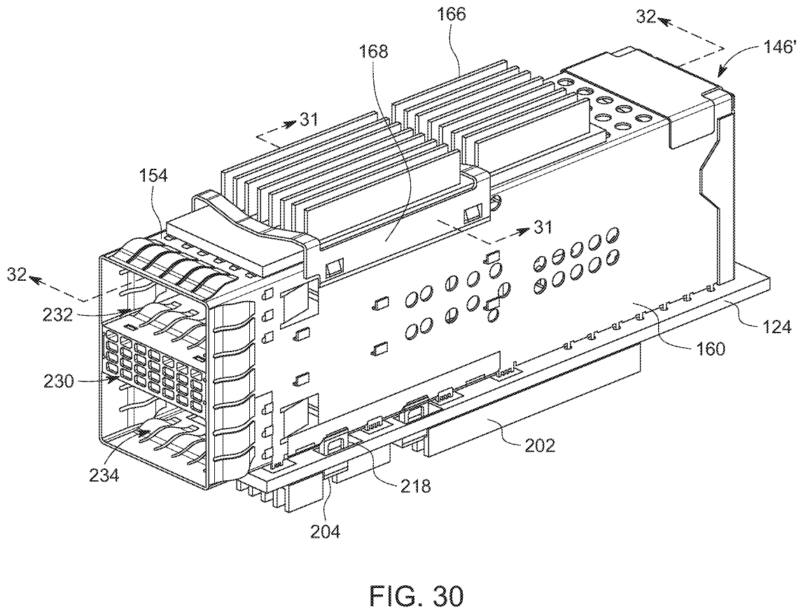

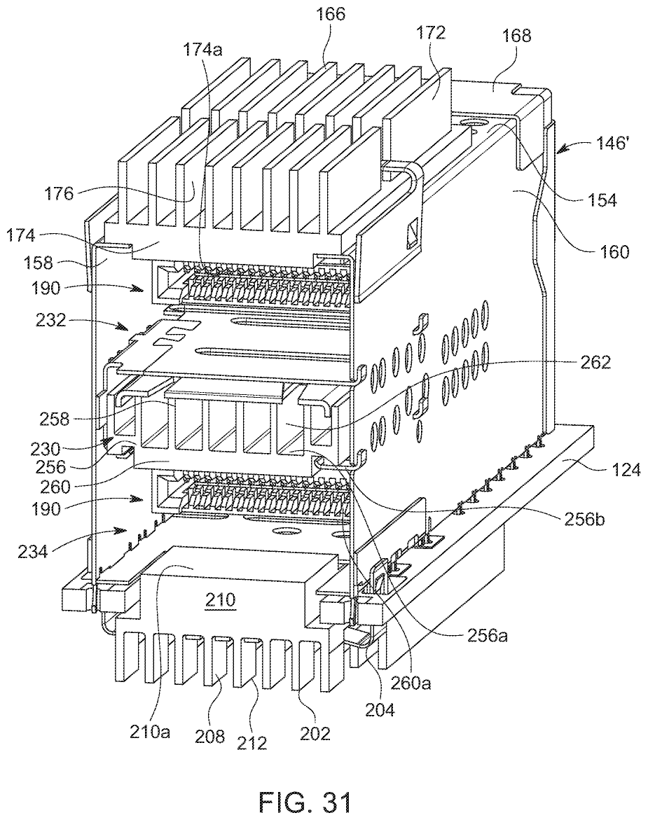

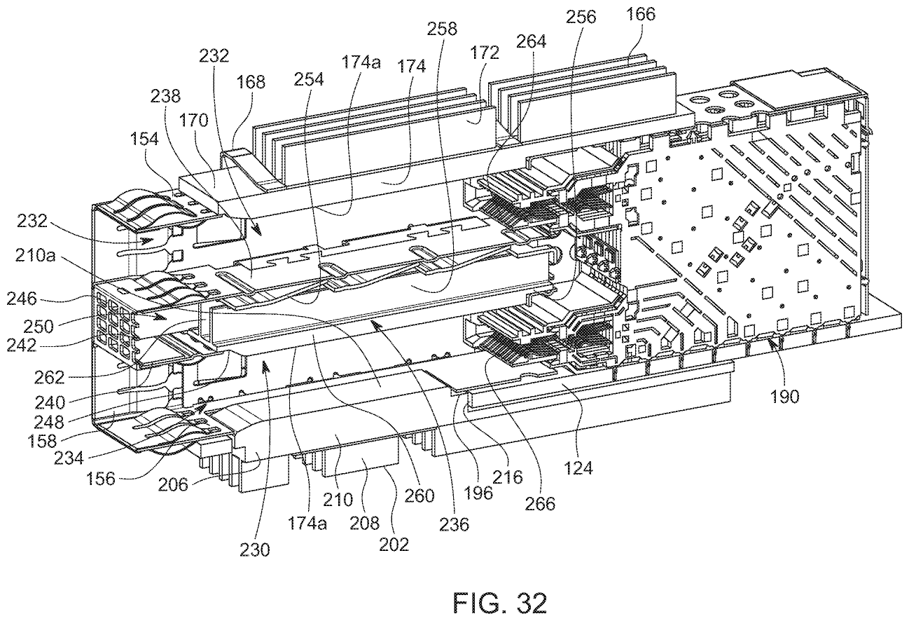

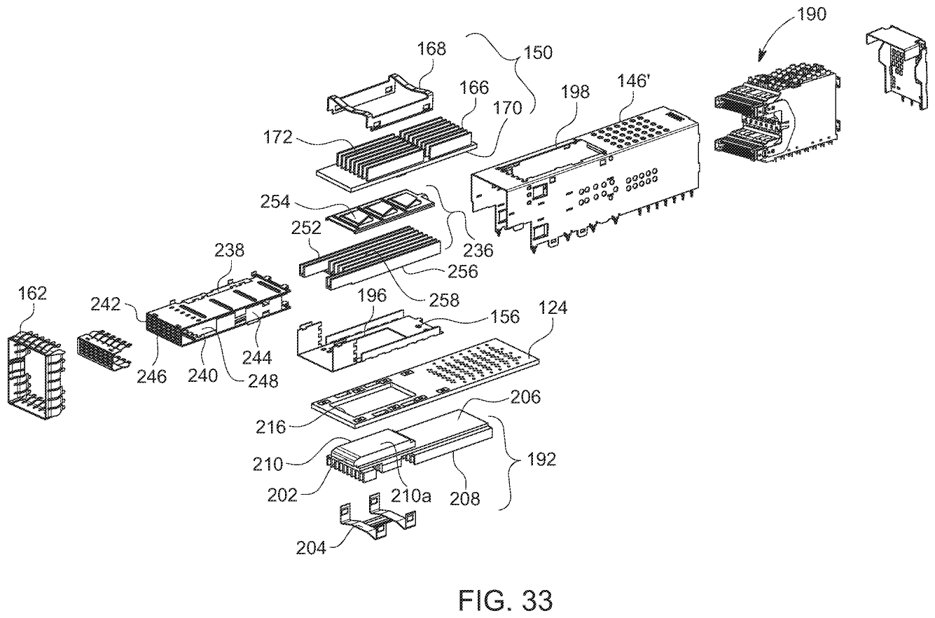

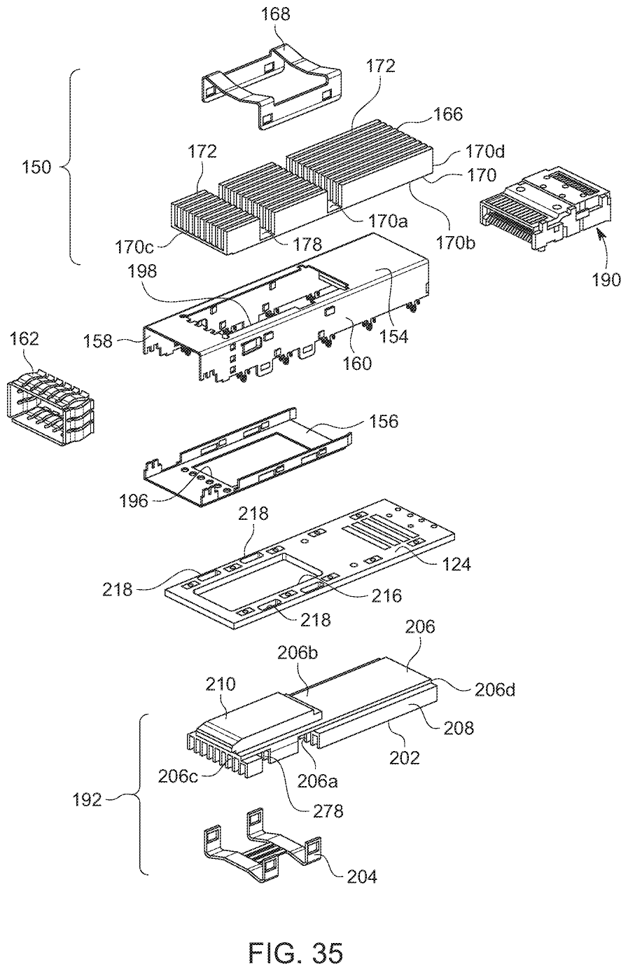

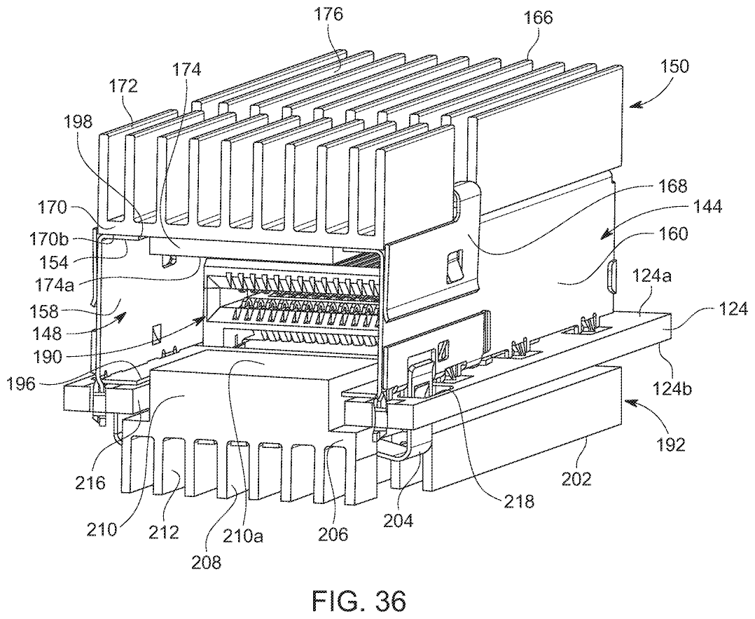

Turning to FIGS. 28-37, embodiments of horizontally aligned ports are provided, one in a stacked configuration and one in a single row version. In each case the I/O connector assemblies are mounted on a card. In one embodiment the card could include a row of contacts like what is shown in FIG. 16 or schematically in FIG. 27B and, like in FIG. 27B, the card assembly would be configured to be inserted into a right angle connector (not shown) so that the ports were provided in a horizontal manner. Cables, similar to what was depicted in the embodiment depicted in FIGS. 13-25, would extended rearward from the I/O connector assembly and provide the high speed signal path. In another embodiment, the card could be part of a larger circuit board and cables for high speed signals would extend rearward from the I/O connector assembly similar to what was depicted in the embodiment depicted FIGS. 13-25. Alternatively, the I/O connector assembly could omit the bipass configuration and just use the card as a standard signal transmission medium. The latter construction would be lower performing from a signal integrity standpoint but could still provide enhanced cooling performance.

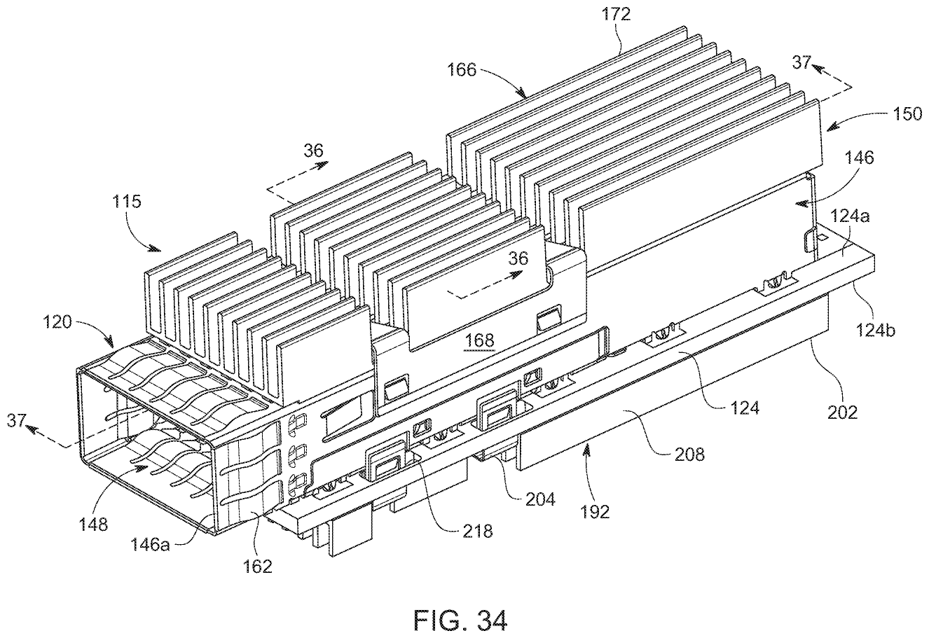

Turning to FIGS. 34-37, a card assembly 115 includes an I/O connector assembly 120 mounted to a card 124. The I/O connector assembly 120—has a conductive cage 146 has a front end 146a and a rear end 146b and the cage 146 defines a port 148 extending from the front end 146a toward the rear end 146b thereof. A receptacle connector 190 is mounted to the card 124 and is positioned in the port 148 and a first heat sink assembly 150 is mounted to an upper side of the cage 146 while a second heat sink assembly 192 is mounted to a lower side of the cage 146, and a cable assembly (not shown) can connected to the receptacle connector 190 in a manner similar to the embodiment depicted in FIGS. 13-25.

The cage 146 includes parallel top and bottom walls 154, 156 and parallel side walls 158, 160 extending between the top and bottom walls 154, 156 at opposite side edges thereof. Inner surfaces of the walls 154, 156, 158, 160 form the port 148. The bottom wall 156 does not extend the full length of the cage 146 such that an opening 194 is formed proximate to the rear end 46b of the cage 46. The bottom wall 156 has an opening 196 therethrough which is rearward of the front end 46a of the cage 46. The top wall 154 has an opening 198 therethrough which is rearward of the front end 46a of the cage 46. The openings 196, 198 may be aligned with each other. Spring fingers 162 may be provided on the walls 154, 156, 158, 160 to assist in connecting the cage 146 to the respective opening 30 in the front wall 28. The cage 146 may be formed by stamping and forming. The cage 146 is thermally conductive and forms a shield assembly for the components mounted therein. When the cage 146 is connected to the front wall 28 of the box 22, the front end 146a of the cage 146 helps define a port that extends through the front wall 28.

The first heat sink assembly 150 is formed from a thermally conductive material and includes a heat sink 166 and a clip 168 which attaches the heat sink 166 to the top wall 154 of the cage 146. As shown, the heat sink 166 includes a base 170 having an upper surface 170a and a planar lower surface 170b which extends from a front end 170c of the base 170 to a rear end 170d of the base 170, a plurality of conductive fins 172 extending outwardly from the upper surface 170a, and a projection 174 extending outwardly from the lower surface 170b. The projection 174 has a planar surface 174a which spaced from the lower surface 170b, but is parallel thereto. The distance between the surfaces 174a, 170b defines a depth of the projection 174. In an embodiment as shown in the drawings, the fins 172 are elongated and extend from the front end 170c to the rear 170d, such that elongated channels 176 are formed therebetween. As shown, multiple sets of fins 172 may be provided, with the sets of fins 172 being separated by sections 178 of the upper surface 170a of the base 170. In an alternative embodiment (not shown), the fins 172 are formed in an array of pillars or some other desirable fin construction.

The lower surface 170b of the base 170 seats against an outer surface of the top wall 154. The projection 174 extends through the opening 198 in the top wall 154 of the cage 146 and into the port 148 thereof. The clip 168 is attached to the side walls 158, 160 to attach the heat sink 166 to the top wall 154 of the cage 146, and in an embodiment, the clip 168 is seated in the sections 178.

The second heat sink assembly 192 is formed from a thermally conductive material and includes a heat sink 202 and a clip 204 which attaches the heat sink 202 to the cage 146. As shown, the heat sink 202 includes a base 206 having a lower surface 206a and a planar upper surface 206b which extends from a front end 206c of the base 206 to a rear end 206d of the base 206, a plurality of conductive fins 208 extending outwardly from the lower surface 206a, and a projection 210 extending outwardly from the upper surface 206b. The projection 210 has a planar surface 210a which spaced from the upper surface 206b, but is parallel thereto. The distance between the surfaces 210a, 206b defines a depth of the projection 210. In an embodiment as shown in the drawings, the fins 208 are elongated and extend from the front end 206c to the rear 206d, such that elongated channels 212 are formed therebetween. As shown, multiple sets of fins 208 may be provided, with the sets of fins 208 being separated by sections 278 of the lower surface 206a of the base 206. In an alternative embodiment (not shown), the fins 208 are formed in an array of pillars or some other desirable fin arrangement.

The card 124 has an opening 216 provided therethrough. When the cage 144 is mounted onto an upper surface 124a of the card 124, the opening 216 aligns with respective opening 196 in the cage 144. As cab be appreciated, while the card assembly in FIGS. 34-37 shows a single I/O connector assembly, in alternative embodiments additional I/O connector assemblies can be provided on the card 124 (provided that the cad 124 is made larger).

The second heat sink assembly 192 is assembled to the card 124 and to the cage 146. The upper surface 206b of the base 206 abuts against a lower surface 124b of the card 124, the projection 210 extends through the opening 216 in the card 124 and further extends through the opening 196 in the bottom wall 156 and into the port 148. The clip 204 extends through aperture 218 in the card 124 and engage with the side walls 158, 160 of the cage 146.

A plug module (not shown) is inserted through the front end 146a of the cage 146, into the port 148 and engages with the receptacle connector 190 in a known manner The plug module forms a primary electromagnetic containment and the cage 146 forms a conductive sleeve around the plug module. When the plug module is inserted into the cage 146, the plug module engages with the surfaces 74a, 210a of the projections 174, 210 and with a card slot of the receptacle connector 190. The clips 168, 204 may allow the base 170, 206 of the respective heat sink 166, 202 to move away from the respective top and bottom walls 154, 156 when the plug module is inserted. To cool the inserted plug module, the fins 172, 208 conduct heat away from the plug module mounted in the cage 146 and dissipate heat by convection and radiation. As can be appreciated, since the projection 210 extends through both of the card 124 and the bottom wall 156 of the cage 146, the projection 210 can have a greater depth than the depth of the projection 174.

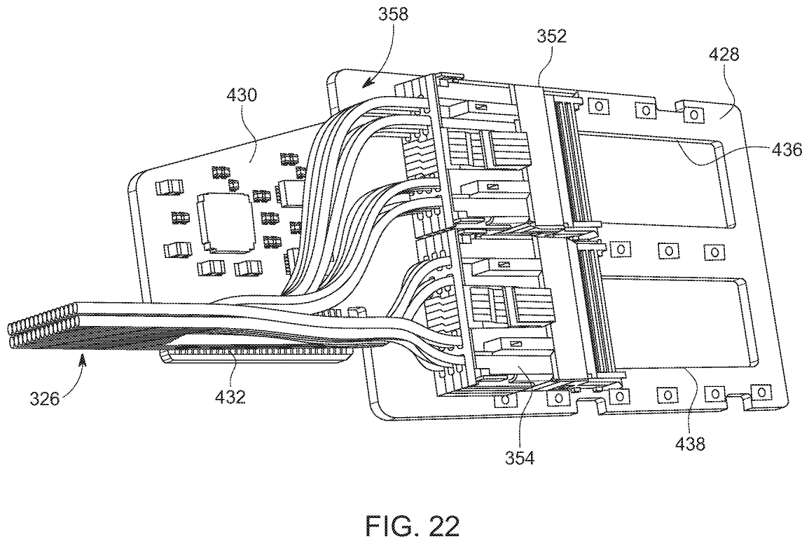

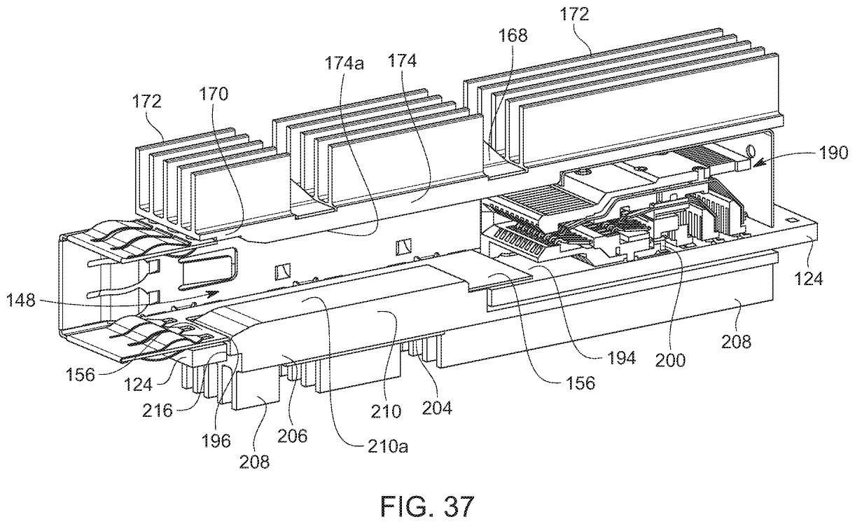

The cage 146 may be mounted to the card 124 either via a surface-mount technology (SMT) operation or via an interference fit using press-fit tails as is known in the art. The receptacle connectors 190 electrically connects with the card 124 to provide a path for all signal (as shown in FIG. 37) or just the low speed signals and power to pass therethrough (as shown with respect to FIG. 22. Thus the features provided in FIGS. 13-25 can also be used with the connector depicted in FIGS. 34-37. The channels 176, 212 between the fins 172, 208 of the connector assemblies 120 align with the air flow openings 38 such that air flows through openings 38 and through the channels 176, 212.

FIGS. 28-33 provide a modified embodiment of a cage 146′ which can be mounted to the card 124 to form the card assembly 120′ (which can include contact pads. not shown). As can be appreciated from FIGS. 28-33, in one embodiment the connector can be a stacked connector and include a top mounted riding heat sink, an internal riding heat sink and a bottom mounted riding heat sink, where the fins of the top and bottom mounted riding heat sinks are positioned on opposite sides of the substrate. and the bottom riding heat sink extends through the substrate and the cage. The embodiment of FIGS. 28-33 have similarities to the embodiment of FIGS. 27A, 27B and 34-37 and only the differences are described herein. As shown in FIGS. 28-33, the cage 146′ has been modified to include an intermediate heat sink assembly housing 230 such that an upper port 232 is provided above the intermediate heat sink assembly housing 230 and a lower port 234 is provided below the intermediate heat sink assembly housing 230. The intermediate heat sink assembly housing 230 provides a mount for a third heat sink assembly 236 within the cage 146′.

The intermediate heat sink assembly housing 230 includes upper and lower walls 238, 240 which are spaced apart from each other, but are connected to each other by a front wall 242 which extends between front ends of the upper and lower walls 238, 240, and support walls 244 extending between the upper and lower walls 238, 240 at positions which are spaced from the front wall 242. The front wall 242 has a plurality of openings 246 therethrough to allow air flow therethrough. The upper and lower walls 238, 240 may have a plurality of openings therethrough to allow air flow therethrough. A heat sink hole 248 is provided through the lower wall 240 and is spaced from the front and rear edges thereof.

The heat sink assembly housing 230 is mounted within the cage 146′ such that side edges of the upper and lower walls 238, 240 are proximate to the inner surfaces of the respective side walls 158, 160 of the cage 146′. The front wall 242 generally aligns with front edges of the walls 154, 156, 158, 160 of the cage 146′. A rear end of heat sink assembly housing 230 aligns with, or generally aligns with, a front edge of the opening 194 through the bottom wall 156. The upper and lower walls 238, 240 are suitably secured to the side walls 158, 160 of the cage 146′, for example by locking tabs seating with apertures. The heat sink assembly housing 230 and portions of the side walls 158, 160 of the cage 146′ form a heat sink assembly retaining space 250 in which the third heat sink assembly 236 is mounted.

The third heat sink assembly 236 is formed from a thermally conductive material and includes a heat sink 252 and a clip 254 which attaches the heat sink 252 to the upper wall 238 of the heat sink assembly housing 230. As shown, the heat sink 252 includes a base 256 having an upper surface 256a and a planar lower surface 256b which extends from a front end of the base 256 to a rear end of the base 256, a plurality of conductive fins 258 extending outwardly from the upper surface 256a, and a projection 260 extending downwardly from the lower surface 256b of the base 256. The projection 260 has a planar surface 260a which spaced from the lower surface 256b, but is parallel thereto. The distance between the surfaces 260a, 256b defines a depth of the projection 260. In an embodiment as shown in the drawings, the fins 258 are elongated and extend from the front end of the base 256 to the rear of the base 256, such that elongated channels 262 are formed therebetween. The lower surface of the base 256 of the heat sink 252 seats against the upper surface of the lower wall 240 and the projection 260 extends through the heat sink hole 248 such that the projection 260 enters into the lower port 234.

The upper port 232 is formed by the top wall 154, an upper portion of the side walls 158, 160 above the upper wall 238 of the intermediate heat sink assembly housing 230, and the upper wall 238 of the intermediate heat sink assembly housing 230. The projection 174 of the first heat sink assembly 150 extends into the upper port 232. The lower port 234 is formed by the bottom wall 156, a lower portion of the side walls 158, 160 below the lower wall 240 of the intermediate heat sink assembly housing 230, and the lower wall 240 of the intermediate heat sink assembly housing 230. The projection 210 of the second heat sink assembly 192 extends into the lower port 234.

When a plug module is inserted into upper port 232 of the cage 146′, the plug module engages with the surfaces 174a, 201a of the projections 174, 210 and with an upper card slot 264 of the receptacle connector 190. To cool the inserted plug module inserted into the upper port 232 of the cage 146′, the fins 175 conduct heat away from the plug module mounted in the upper port 232 of the cage 146′and dissipate heat by convection. When a plug module is inserted into the lower port 234 of the cage 146′, the plug module engages with the projections 210, 260 and with a lower card slot 266 of the receptacle connector 190. The clips 204, 254 may allow the base 206, 256 of the respective heat sink 202, 252 to move away from the respective lower walls 156, 240 when the plug module is inserted. To cool the inserted plug module inserted into the lower port 234 of the cage 146′, the fins 208, 258 conduct heat away from the plug module mounted in the lower port 234 of the cage 146′and dissipate heat by convection.

The use of heat sinks 252, 202 on opposite sides of the inserted lower plug module allows for decreased thermal resistance between the lower plug module and the cooler air, and thus helps improve thermal performance under load. As can be appreciated, with the depicted design an inserted lower plug module can be cooled from both sides while keeping the fins 258, 208 shorter to help reduce the thermal resistance between the inserted plug module and the end of the fins 404, 420. Since the projection 210 extends through both of the front circuit board 124 and the bottom wall 156 of the cage 146′, the projection 210 has a greater depth than the depth of the projection 260. The projections 174, 260 may have the same depth.

While the front circuit board 124 is shown positioned below the I/O connector assemblies 20 in FIGS. 27A-37, the components can be flipped in the box 22 such that the front circuit board 124 is positioned above the I/O connector assemblies 20 in the box 22.

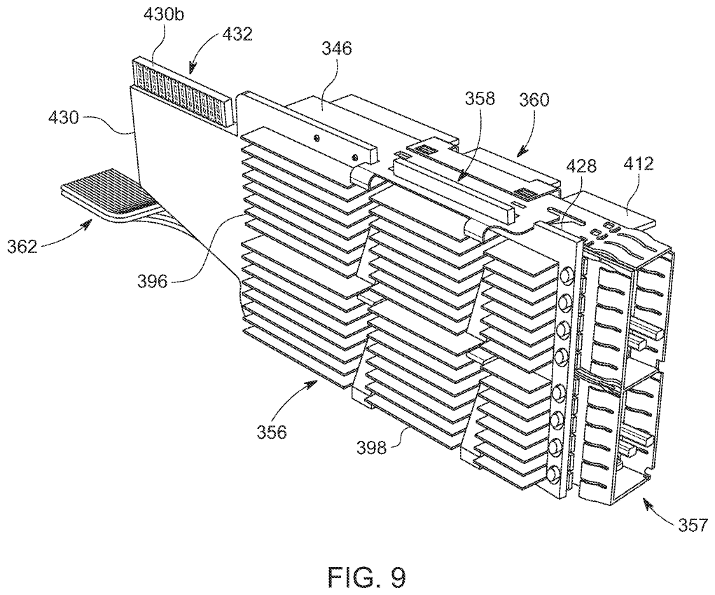

FIGS. 3-25 depict an embodiment of a plurality of card assemblies 357 housed in a box 322 which provides enhanced thermal dissipation. Rather than mount the two IO connectors in a belly to belly arrangement (which typically requires that the plug in the top port has the opposite orientation of the plug in the bottom port and is shown in FIG. 1), the ports are arranged vertically with a top port sharing a side with a bottom port by providing a card assembly 357 (FIG. 9) that supports the two IO ports, which could be QSFP connectors or any other desirable connector configuration. The I/O connector assemblies 320 are mounted to and electrically connected to a front circuit board 324 which is horizontally mounted in the box 322 for transmitting low speed signals from the I/O connector assemblies 320 thereto. The connector assemblies 320 are further connected to a rear circuit board 326 in a bypass arrangement for transmitting high speed signals from the I/O connector assemblies 320 to the rear circuit board 326. Plug modules (not shown) can be inserted in the I/O connector assemblies 320. The plug modules may be Quad Small Form Factor (QSFP) transceiver modules or any other suitable module configuration (such as, without limitation, QSDP-DD, SFP, CXP, OSFP, etc.). High speed signals from the plug modules are routed via cables from the I/O connector assemblies 320 to the rear circuit board 326. Low speed signals and power are routed via the circuit board 324. It should also be noted that in certain embodiments the rear circuit board 326 and the circuit board 324 can be the same circuit board.

The box 322 (not show in its entirety as only the front wall is shown) is typically rectangular in shape (like a typical switch that can be mounted in a rack system) and can have the traditional six sides with a front wall 328 having a front face 328a that has a plurality of pairs of stacked openings 330 provided therethrough formed in rows and columns Each opening 330 is provided by an I/O connector assembly and extends vertically relative to top and bottom edges 328b, 328c of the front wall 328. As such, a top row 332 of spaced apart openings 330 is provided, and a bottom row 334 of spaced apart openings 330 is provided. Adjacent pairs of openings 330 (one in the top row 332 and one in the bottom row 334) are spaced apart from each other by a section 336 of the front wall 328. As shown, the openings 330 form sets two openings 330 between sections 336, however in other embodiments the numbers of openings 330 may vary. Each section 336 of the front wall 328 has a plurality of air flow openings 338 provided therethrough which allow air to flow through the front wall 328 to cool the I/O connector assemblies 320 mounted therein. Thus, the front wall 328 can be configured to decrease air resistance so as to allow for more air to flow through the box 322 for a given air pressure gradient.

A frame-like structure can be provided in the box and can include side walls 342, 344 that extend rearwardly from the front wall 328 along with a top brace 340. The front circuit board 324 is mounted in a horizontal orientation and can be positioned below the bottom row 334 of openings 330.

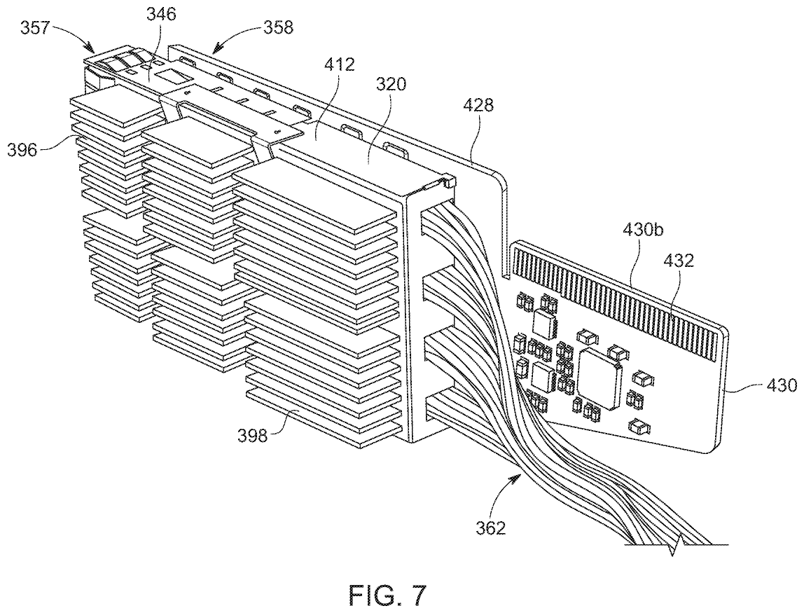

Examples of card assemblies are shown in FIGS. 7, 16 and 19. Notably, the embodiment in FIG. 7 only includes a first heat sink on one side of a card and omitting a second heat sink on a second side of the card). As can be appreciated, for additional cooling, the card can have an aperture in the middle and a second heat sink assembly can be mounted thereon so that the second heat sink assembly has projections that extend into the cage. As with the first heat sink assembly, the heat sink can be a single unit or multiple units. For example, in an embodiment the heat sink can be a riding heat sink such as is known. Naturally the use of two riding heat sinks on opposite sides of the module allows for decreased thermal resistance between the module and the cooler air and thus helps improve thermal performance under load. The ability to have both heat sinks flex potentially allows for stiffer retaining clips on both sides that collectively equal the stiffness of what would normally be a single retaining clip. The expectation is that such an increase in stiffness may provide an improved thermal interface on both sides of the inserted module while providing a consistent level of insertion force. As can be appreciated, therefore, in certain embodiments an inserted module can be cooled from both sides while keeping the fins shorter to help reduce the thermal resistance between the inserted module and the end of the fins.

As can be appreciated, the card may have two apertures, one aligned with each port. Such a configuration allows for a center portion of the card to accept mounting tails from the cage and thus potentially provides a more secure/robust structure. Such a construction is not required, however and a single aperture that is aligned with both ports is also suitable for certain applications. In an embodiment the apertures are sized so that the connector extends over the aperture. In such an embodiment, as can be appreciated, the increased size of the aperture allows for greater surface area for the mating heat sink to engage an inserted module. Naturally, the size of the aperture (and the corresponding size of the projection on the heat sink) can be adjusted to account for thermal performance requirements.

As depicted, the contact pads on the card are positioned between a top and bottom edge of the card. Conventional cards have contact pads on the bottom for stability purposes and the depicted embodiment would be less desirable from a stability standpoint. Having the contact pads offset from the top or bottom, however, allows for improvements in packaging that has been determined in certain cases to be more valuable than the stability provided by a conventional design. Additional stability, if desired, can be provided by ensuring the cage securely engages a front panel.

As depicted, the card assembly 357 has the I/O connector assemblies 320 mounted on a card 358 and each I/O connector assembly 320 includes a conductive cage 346 having a front end 346a and a rear end 346b and the respective conductive cage 346 defines the opening 330 and further defines an upper port 348 extending from the front end 346a toward the rear end 346b thereof and a lower port 350 extending from the opening 330 in front end 346a toward the rear end 346b thereof. The card assembly 357 further includes an upper receptacle connector 352 mounted in the upper port 348 of the cage 346, and a lower receptacle connector 354 mounted in the lower port 350 of the cage 346. Both of the receptacle connectors 352, 354 have a front edge 391. The card assembly 357 further includes a first heat sink assembly 356 mounted to the cage 346, the card 358, which can be a conventional circuit board or some other substrate with a desired configuration, to which the cage 346 and the receptacle connectors 352, 354 are mounted to one side thereof, and a second heat sink assembly 360 mounted to the cage 346 and to the card 358. The card assembly 357 further includes a cable assembly 362 connected to the receptacle connectors 352, 354. As can be appreciated, the card 358 can be positioned vertically within the box 322 and thus be perpendicular to the front circuit board 324. It should be noted that the card assembly 357 can be mounted with the contact pads 432 facing upward or downward. As a result, the use of upper and lower ports is for ease of discussion as the orientation can be reversed depending on how the card assembly 357 is mounted in the box.

The cage 346 includes an upper wall 364, parallel side walls 366, 368 extending downwardly therefrom at opposite side edges thereof to a lower wall 370 which is parallel to the upper wall 364. An intermediate wall 372 extends between the side walls 366, 368 and is parallel to the upper and lower walls 364, 366. The upper port 348 is formed by the upper wall 364, an upper portion of the side walls 366, 368 and the intermediate wall 372. The lower port 350 is formed by the lower wall 370, a lower portion of the side walls 366, 368 and the intermediate wall 372.

The side wall 366 has an upper opening 374 proximate to the front end 346a of the cage 346 above the intermediate wall 372 and which is in communication with the upper port 348. The upper opening 374 has a front edge 374a, an opposite rear edge 374b and top and bottom edges 374c, 374d extending between the front and rear edges 374a, 374b. In an embodiment, the upper opening 374 is rectangular. The side wall 368 further has a lower opening 376 proximate to the front end 346a of the cage 346 below the intermediate wall 372 and which is in communication with the lower port 350. The lower opening 376 has a front edge 376a, an opposite rear edge 376b and top and bottom edges 376c, 376d extending between the front and rear edges 376a, 376b. In an embodiment, the lower opening 376 is rectangular. The openings 374, 376 are aligned with each other.

The side wall 368 has an upper opening 378 proximate to the front end 346a of the cage 346 above the intermediate wall 372 and which is in communication with the upper port 348. The upper opening 378 has a front edge 378a, an opposite rear edge 378b and top and bottom edges 378c, 378d extending between the front and rear edges 378a, 378b. In an embodiment, the upper opening 378 is rectangular. The side wall 368 further has a lower opening 380 proximate to the front end 346a of the cage 346 below the intermediate wall 372 and which is in communication with the lower port 350. The lower opening 380 has a front edge 380a, an opposite rear edge 380b and top and bottom edges 380c, 380d extending between the front and rear edges 380a, 380b. In an embodiment, the lower opening 380 is rectangular. The openings 378, 380 are aligned with each other.

The side wall 368 has an upper opening 382 at the rear end 346b of the cage 346 above the intermediate wall 372 and which is in communication with the upper port 348. The upper receptacle connector 352 is mounted through the upper opening 382 and into the upper port 348. The side wall 368 further has a lower opening 384 at the rear end 346b of the cage 346 below the intermediate wall 372 and which is in communication with the lower port 350. The lower receptacle connector 354 is mounted through the lower opening 384 and into the lower port 350. The openings 382, 384 are aligned with each other such that the receptacle connector 354 is above the receptacle connector 352.

Spring fingers 386 may be provided on the walls 364, 366, 368, 370 to assist in connecting the cage 346 to the front wall 328 of the box 322. The cage 346 may be formed by stamping and forming. The cage 346 is thermally conductive and forms a shield assembly for the components mounted therein. When the cages 346 are connected to the front wall 328 of the box 322, the front ends 346a of the cages 346 form ports through the front wall 328.

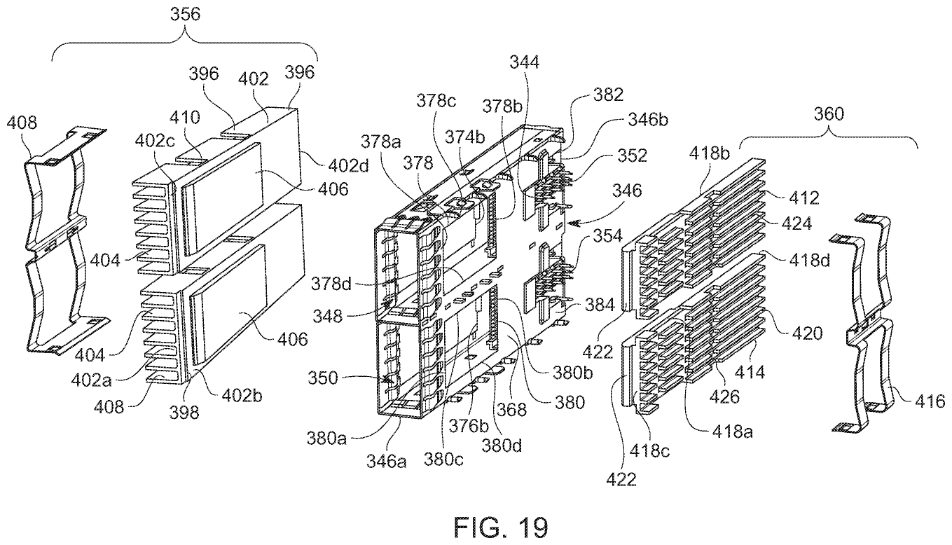

The receptacle connectors 352, 354 are shown in FIGS. 19-21. Each receptacle connector 352, 354 includes a housing 388 have a card slot 390 open to a front end thereof, and into which a paddle card (not shown) of the plug module is received. A plurality of terminals within the card slot 390 connect with the paddle card. As depicted, each receptacle connector 352, 354 further has a plurality of laterally spaced wafers 392 which connect with the cable assembly 362. It should be noted that other configurations are contemplated such as having the high-speed signals configured in vertical wafers (relative to the horizontal card slot) while low speed signal are connected to the card 358 in a group similar to conventional SMT style terminals. High speed signals are transmitted from the plug module, through the terminals in the card slot 390 and then to the cable assembly 362. Low speed signals and power are routed via the paddle card, terminals 394 in the receptacle connector which extend through the side wall 368 and which are connected to the card 358. In an embodiment, the front ends of the receptacle connectors 352, 354 are rearward of the rear edges 378b, 380b of the openings 378, 380. In an alternate embodiment, the front ends of the receptacle connectors 352, 354 overlap the rear edges 378b, 380b of the openings 378, 380.

The first heat sink assembly 356 is formed from a thermally conductive material and includes an upper heat sink 396, a lower heat sink 398, and a clip 400 which attaches the heat sinks 396, 398 to the side wall 366 of the cage 346. As shown, each heat sink 396, 398 includes a base 402 having a first side surface 402a and a planar second side surface 402b which extends from a front end 402c of the base 402 to a rear end 402d of the base 402, a plurality of conductive fins 404 extending outwardly from the first side surface 402a, and a projection 406 extending outwardly from the second side surface 402b. Each projection 406 has a planar surface 406a which spaced from the second side surface 402b but is parallel thereto. The distance between the surfaces 406a, 402b defines a depth of each projection 406. In an embodiment as shown in the drawings, the fins 404 are elongated and extend from the front end 402c to the rear 402d, such that elongated channels 408 are formed therebetween. As shown, multiple sets of fins 404 may be provided, with the sets of fins 404 being separated by sections 410 of the first side surface 402a of the base 402. In an alternative embodiment (not shown), the fins 404 are formed in an array of pillars.

The second side surface 402b of the base 402 of the upper heat sink 396 seats against an outer surface of the side wall 366. The projection 406 of the upper heat sink 396 extends through the upper opening 374 in the side wall 366 of the cage 346 and into the upper port 348 thereof. The second side surface 402b of the base 402 of the lower heat sink 398 seats against an outer surface of the side wall 366. The projection 406 of the lower heat sink 398 extends through the lower opening 376 in the side wall 366 of the cage 346 and into the lower port 350 thereof. The clip 400 attaches to the top and bottom walls 154, 156 to attach the heat sinks 396, 398 to the side wall 366 of the cage 146, and in an embodiment, the clip 400 is seated in the sections 410.

The second heat sink assembly 360 is formed from a thermally conductive material and includes an upper heat sink 412, a lower heat sink 414, and a clip 416 which attaches the heat sinks 412, 414 to the side wall 366 of the cage 346. As shown, each heat sink 412, 414 includes a base 418 having a first side surface 418a and a planar second side surface 418b which extends from a front end 418c of the base 418 to a rear end 418d of the base 418, a plurality of conductive fins 420 extending outwardly from the first side surface 418a, and a projection 422 extending outwardly from the second side surface 418b. Each projection 422 has a planar surface 422a which spaced from the second side surface 418b but is parallel thereto. The distance between the surfaces 422a, 418b defines a depth of each projection 422. In an embodiment as shown in the drawings, the fins 420 are elongated and extend from the front end 418c to the rear 418d, such that elongated channels 424 are formed therebetween. As shown, multiple sets of fins 420 may be provided, with the sets of fins 420 being separated by sections 426 of the first side surface 418a of the base 418. In an alternative embodiment (not shown), the fins 420 are formed in an array of pillars.

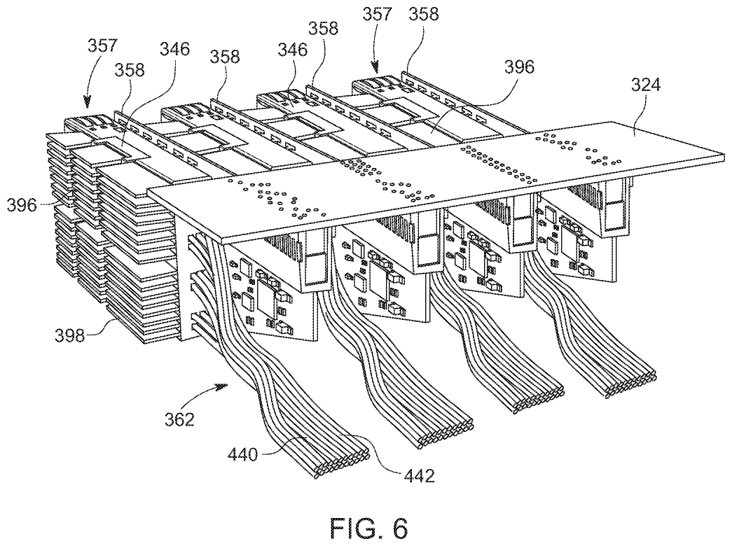

The card 358 has a front portion 428 which overlays and is connected to the side wall 368 of the cage 346, and a rear portion 430 which extends outwardly from the rear end of the front portion 428 and the rear end 326b of the cage 346. The rear portion 430 has a plurality of contact pads 432, which are arranged in a row, provided on an edge thereof and which connect to the front circuit board 324 by connectors 434. The rear portion 430 thus provides a mounting flange for attachment of the card 358 to the front circuit board 324. In an embodiment, the contact pads 432 are provided on a lower edge 430a of the rear portion 430 and the front circuit board 324 lays below the rear portions 430; the connector 434 is used to electrically connect the contact pads 432 to the front circuit board 324 such that the front circuit board 324 is supported by the card 358. In an embodiment as shown in FIGS. 6-11, the contact pads 432 are provided on an upper edge 430b of the rear portion 430 (it being understood that rotating the card 180 degrees would cause the upper edge to be a lower edge) and the front circuit board 324 lays on top of the rear portions 430 430; a connector is used to electrically connect the contact pads 432 on each rear portion 430 to the front circuit board 324 such that the front circuit board 324 is supported by the card 358 (or in alternative embodiments, the circuit board 324 helps support the card 358). It should be noted that the connector 434 is shown as a vertical style board connector (in that the mating contact pads are inserted into the connector 434 in a vertical direction). In an embodiment, the contact pads 432 are provided on a rear edge 430c of the rear portion 430 and the front circuit board 324 lays on top of the rear portions 430 or below the rear portions 430; a right-angle connector is used to electrically connect the contact pads 432 to the front circuit board 324 such that the front circuit board 324 is supported by the card 358. In an embodiment, the contact pads 432 are provided on the upper edge 430b of the rear portion 430 and on the rear edge of the rear portion 430; the front circuit board 324 lays on top of the rear portions 430 and are connected to the contact pads 432 by connectors such that the front circuit board 324 is supported by the card 358. In an embodiment, the contact pads 432 are provided on the lower edge 430a of the rear portion 430 and on the rear edge 430c of the rear portion 430; the front circuit board 324 lays below the rear portions 430 and are connected to the contact pads 432 by connectors such that the front circuit board 324 is supported by the card 358. In an embodiment, the contact pads 432 are provided on the lower and upper edges 430a, 430b of the rear portion 430; a first front circuit board 324 lays above the rear portions 430 and are connected to the contact pads 432 on the upper edge by connectors such that the first front circuit board 324 is supported by the card 358; and a second front circuit board 324 lays below the rear portions 430 and are connected to the contact pads 432 on the lower edge by connectors such that the second front circuit board 324 is supported by the card 358.

When the front circuit board 324 is connected to the lower edges 430a of the rear portions 430, the lower edge 430a of each rear portion 430 is vertically spaced above the lower wall 370 of the respective cage 346. When the front circuit board 324 is connected to the upper edges 430b of the rear portions 430, the upper edge 430b of each rear portion 430 is vertically spaced below the upper wall 364 of the respective cage 346. This provides a space for the front circuit board 324 to be positioned directly behind the cage 346 and not use additional vertical space in the box 322.

The side wall 368 of the cage 346 is attached to the front portion 428, such that the rear portion 430 is cantilevered outwardly from the cage 346. The side wall 368 of the cage 346 is connected to the card 358 either via a surface-mount technology (SMT) operation or via an interference fit using press-fit tails as is known in the art. If the cages 346 are pressed on the card 358 with the use of press-fit tails then a solder operation is not needed and additional choices in the types of materials that will work are possible. The receptacle connectors 352, 354 are electrically connected to the card 358 and may be surface-mounted to the card 358, or may have press-fit tails which extend into conductive vias in the card 358 as is known in the art.

The front portion 428 of the card 358 has an upper opening or port 436 proximate to the front end 346a of the cage 346 above the intermediate wall 372 and which is in communication with the upper port 348. The upper port 436 has a front edge 436a, an opposite rear edge 436b and top and bottom edges 436c, 436d extending between the front and rear edges 436a, 436b. In an embodiment, the upper port 436 is rectangular. The card 358 further has a lower aperture 438 proximate to the front end 346a of the cage 346 below the intermediate wall 372 and which is in communication with the lower port 350. The lower aperture 438 has a front edge 438a, an opposite rear edge 438b and top and bottom edges 438c, 438d extending between the front and rear edges 438a, 438b. In an embodiment the front edge 391 of the receptacle connectors extends past the rear edge 43 8b and thus the receptacle connector can overlap the aperture 438 (and similarly the aperture 436). In an embodiment, the lower aperture 438 is rectangular. The apertures 436, 438 are aligned with each other. In an embodiment, a front edge 428a of the front portion 428 aligns with the front end 346a of the cage 346, a rear edge 428b of the front portion 428 is rearward of the rear end 346b of the cage 346, a top edge 428c of the front portion 428 aligns with the upper wall 364 of the cage 346, and a bottom edge 428d of the front portion 428 aligns with the lower wall 370 of the cage 346. A first planar side surface 428e extends between the edges 428a-428d abuts against the side wall 368, and a second planar side surface 428f extends between the edges 428a-428d on the opposite side of the front portion 428.

The rear portion 430 of the card 358 has a first planar side surface 430d that extends between the edges 430a-430c and is coplanar with the first planar side surface 428e of the front portion 428, and a second side surface 430e that extends between the edges 430a-430c on the opposite side of the rear portion 430 and is coplanar with the second side surface 428f.

The second heat sink assembly 360 is assembled to the card 358 and to the cage 346 by the clip 416. The second side surface 418b of the base 418 of the upper heat sink 412 seats against the second side surface 428f of the card 358. The projection 422 of the upper heat sink 412 extends through the upper aperture 436 in the card 358, through the upper opening 378 in the side wall 368 of the cage 346 and into the upper port 348 thereof. The second side surface 418b of the base 418 of the lower heat sink 414 seats against the second side surface 428f of the card 358. The projection 422 of the lower heat sink 414 extends through the lower aperture 438 in the card 358, through the lower opening 380 in the side wall 368 of the cage 346 and into the lower port 350 thereof. The clip 416 extends through openings 216 in card 358 and engage with the upper and lower walls 364, 370 of the cage 346. In an embodiment, the clip 400 is seated in the sections 410.

A plug module (not shown) is inserted through the front end 346a of the cage 346, into the upper port 348 and engages with the upper receptacle connector 352 in a known manner. The plug module forms a primary electromagnetic containment and the cage 346 forms a conductive sleeve around the plug module. When the plug module is inserted into the upper port 348 of the cage 346, the plug module engages with the surfaces 406a, 422a projections 406, 422 of the upper heat sinks 396, 412 and with the card slot 390 of the upper receptacle connector 352. The clips 400, 416 may allow the base 402, 418 of the respective upper heat sink 396, 412 to move away from the respective side walls 366, 368 when the plug module is inserted into the upper port 348. To cool the plug module inserted into the upper port 348, the fins 404, 420 conduct heat away from the plug module inserted into the upper port 348 and can dissipate heat by convection.

Likewise, a plug module (not shown) is inserted through the front end 346a of the cage 346, into the lower port 350 and engages with the lower receptacle connector 354 in a known manner. The plug module forms a primary electromagnetic containment and the cage 346 forms a conductive sleeve around the plug module. When the plug module is inserted into the lower port 350 of the cage 346, the plug module engages with the surfaces 406a, 422a on the projections 406, 422 of the lower heat sinks 398, 414 and with the card slot 390 of the lower receptacle connector 354. The clips 400, 416 may allow the base 402, 418 of the respective lower heat sink 398, 414 to move away from the respective side walls 366, 368 when the plug module is inserted into the lower port 350. To cool the plug module inserted into the lower port 350, the fins 404, 420 conduct heat away from the plug module inserted into the lower port 350 and dissipate heat by convection. As a result, this embodiment allows each plug module to be inserted into the ports 348, 350 in the same direction.

As depicted, since the projections 422 extends through both of the card 358 and the side wall 368 of the cage 146′, the projection 422 has a greater depth than the depth of the projections 406. As can be appreciated, while the base 402 of the upper heat sink 396 is shown separated from the base 402 of the lower heat sink 398, a single continuous base can be provided.

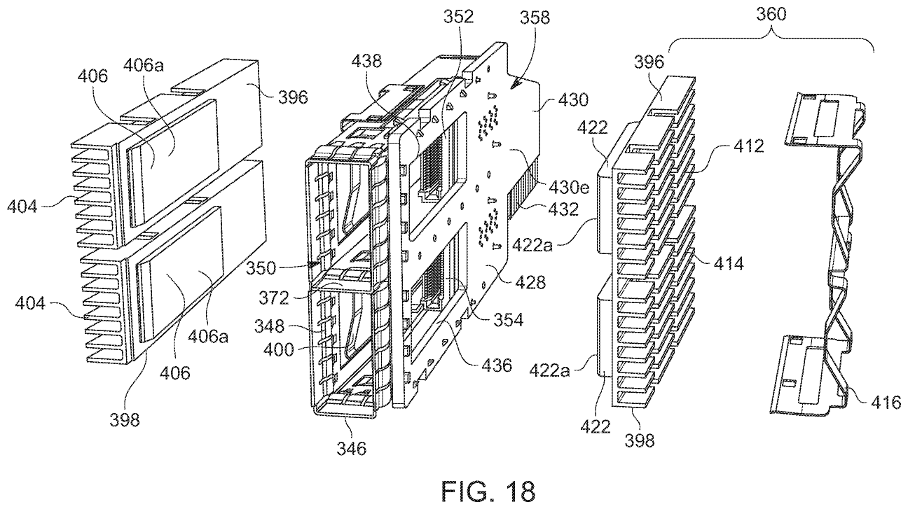

While the base 418 of the upper heat sink 412 is shown separated from the base 418 of the lower heat sink 414, a single continuous base can be provided as shown in FIG. 18. While two separate apertures 436, 438 are shown in the drawings through the card 358, a single opening can be provided therethrough which will accommodate both projections 422 on the upper and lower heat sinks 412, 414.

The use of heat sinks 396, 398, 414, 416 on opposite sides of each plug module allows for decreased thermal resistance between the plug module and the cooler air, and thus helps improve thermal performance under load. As can be appreciated, with the depicted design an inserted plug module can be cooled from both sides while keeping the fins 404, 420 shorter to help reduce the thermal resistance between the inserted plug module and the end of the fins 404, 420.

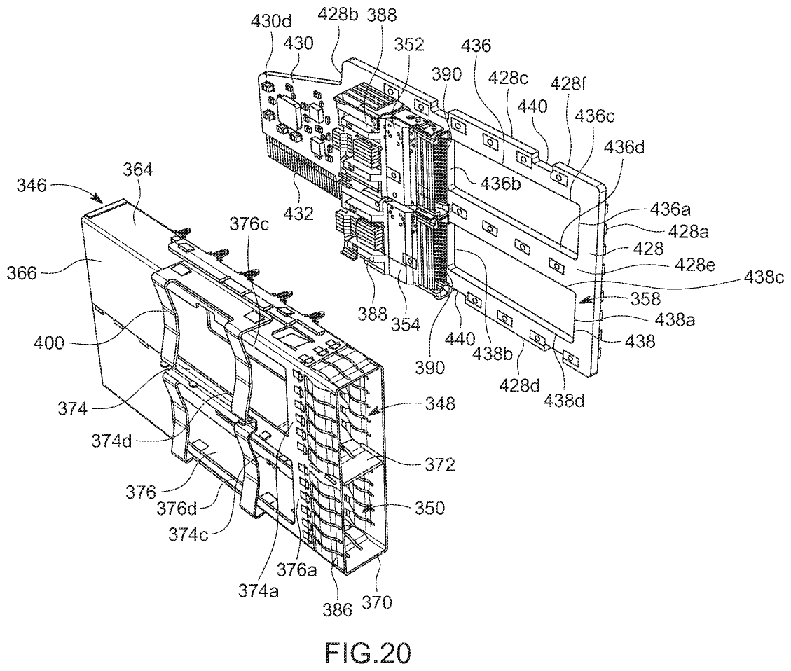

As shown in FIG. 20, the front end of the receptacle connector 352, 354 can overlap the rear end 436b, 438b of the respective apertures 436, 438. The projections 422 on the upper and lower heat sinks 412, 414 may be contact with the front ends of the receptacle connectors 352, 354 that overlap the rear end 436b, 438b of the respective apertures 436, 438. This assists in dissipating heat from the receptacle connectors 352, 354.

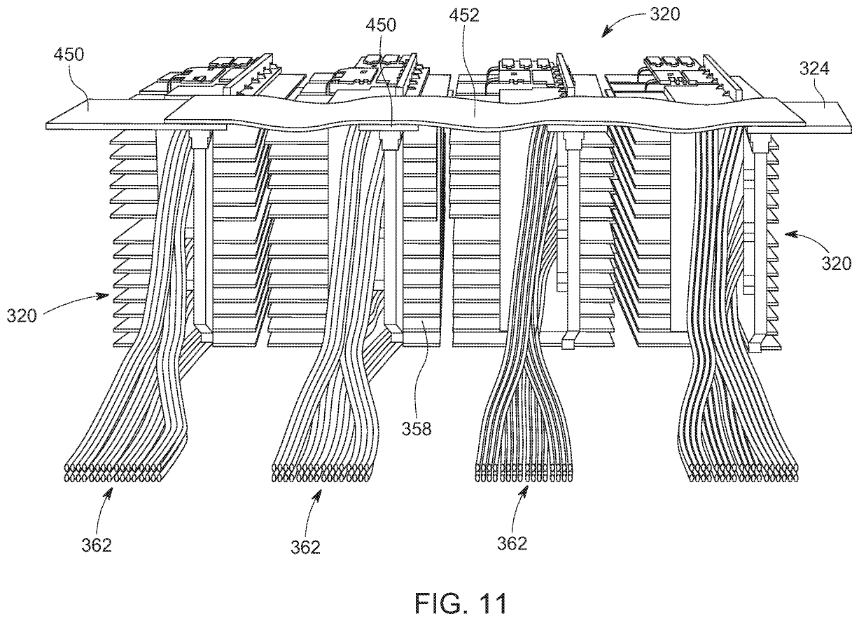

The cable assembly 362 includes a plurality of cables 440 connected to the upper receptacle connector 352 for transmitting high speed signals from the plug module to the rear circuit board 326, and plurality of cables 442 connected to the lower receptacle connector 354 for transmitting high speed signals from the plug module to the rear circuit board 326. The cables 440 are terminated with connectors 446 and the cables 442 are terminated with a connector 448. As shown in FIG. 11, the front circuit board 324 can be formed of rigid sections 450 attached to the cards 358 on which the connectors 434 are mounted and a flex circuit 452 connecting the rigid sections 450 together. As can be appreciated, when adjacent card assemblies 357 are mounted on the front circuit board 324, the fins 404 on the heat sink assembly 356 faces the fins 420 on the heat sink assembly 360 on adjacent card assemblies as shown in FIG. 13.

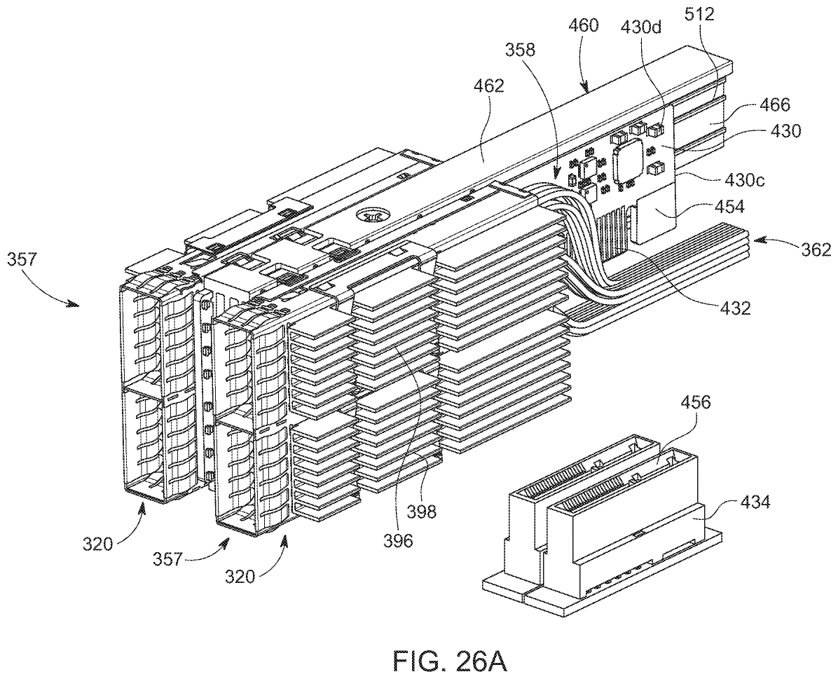

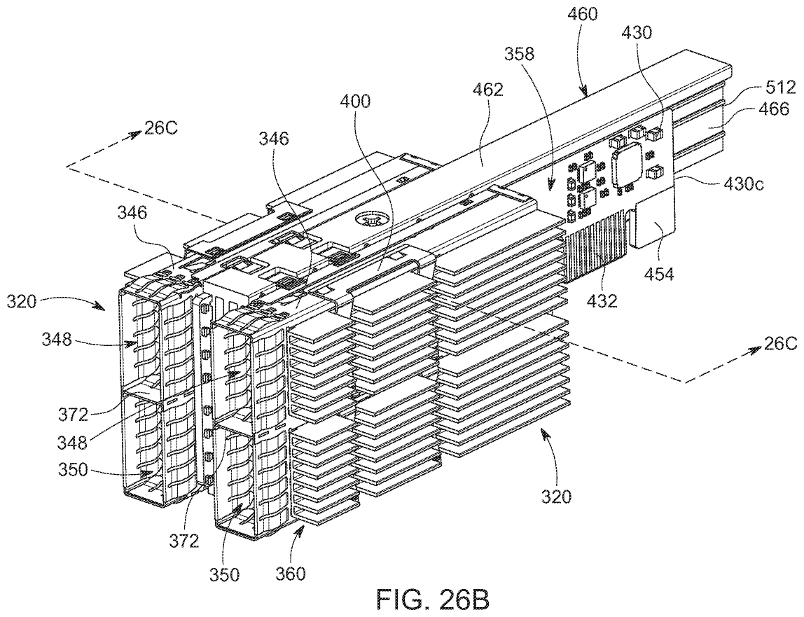

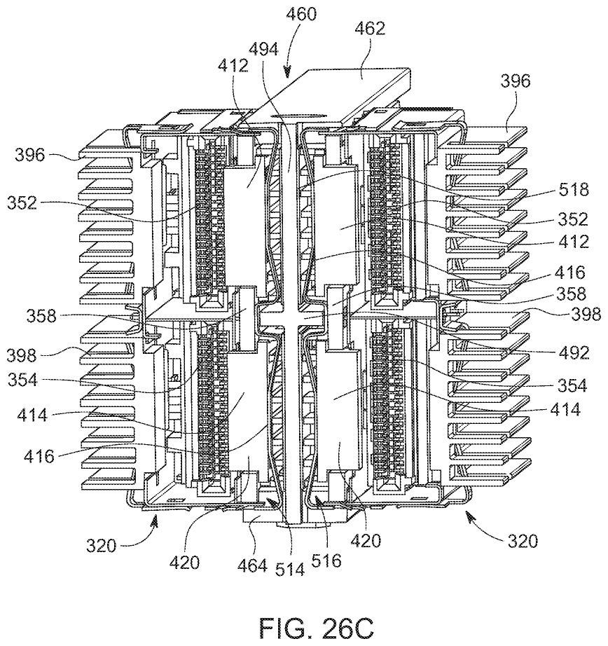

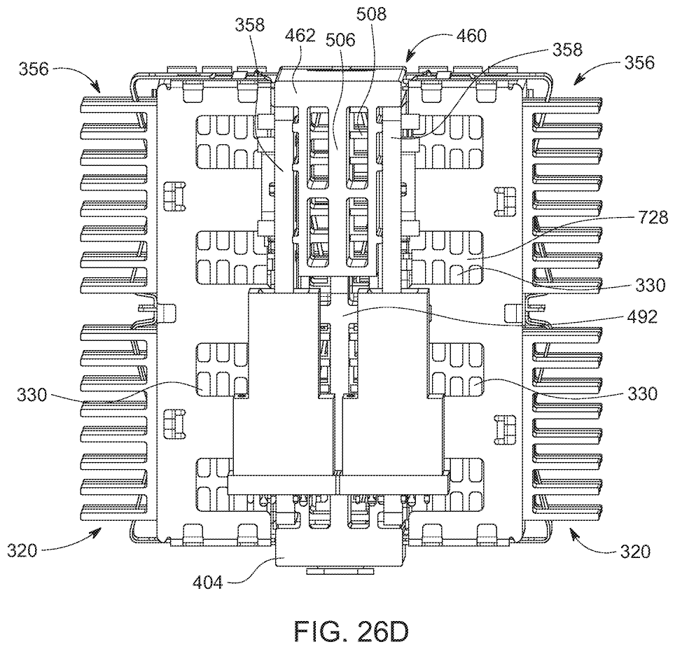

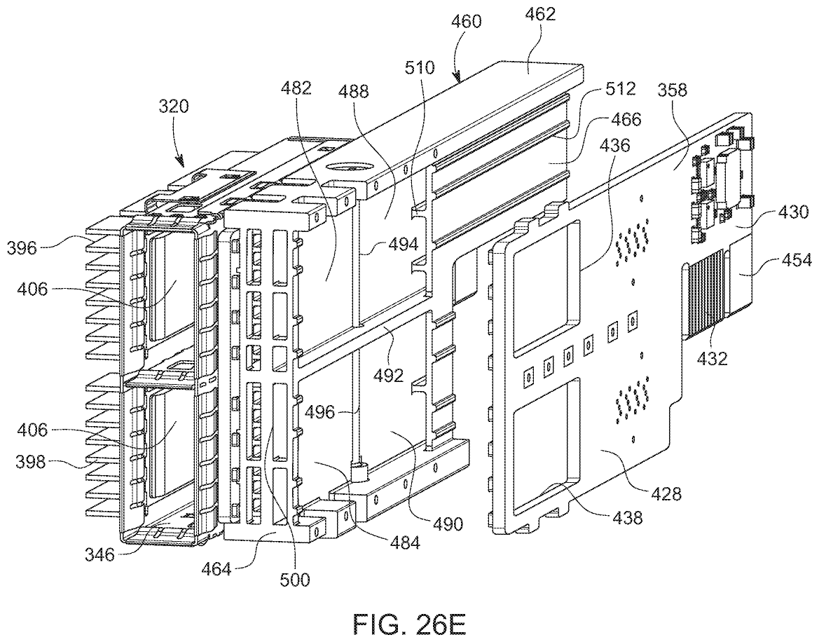

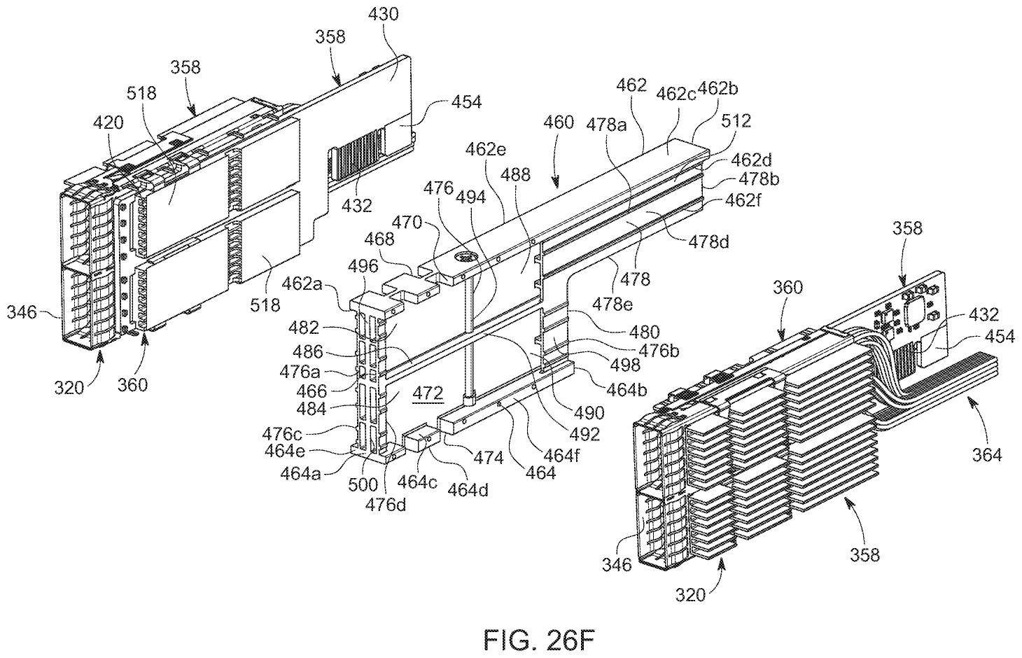

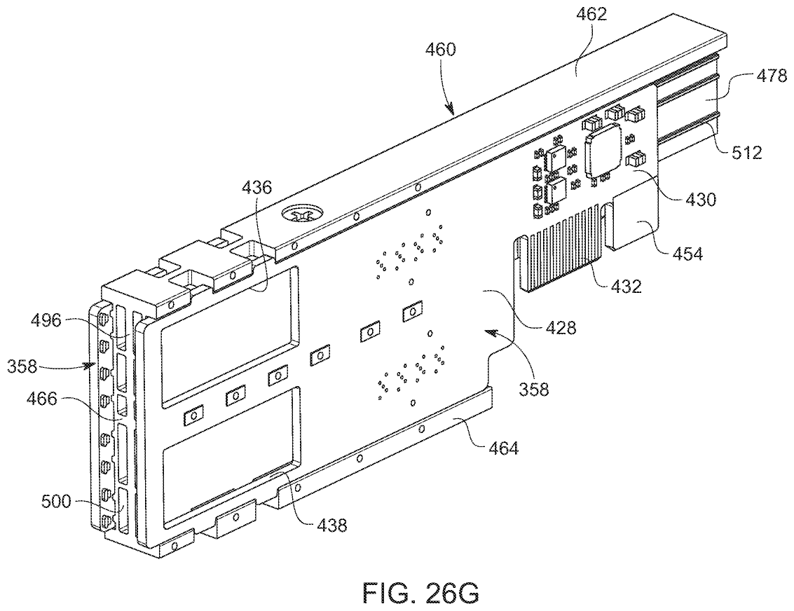

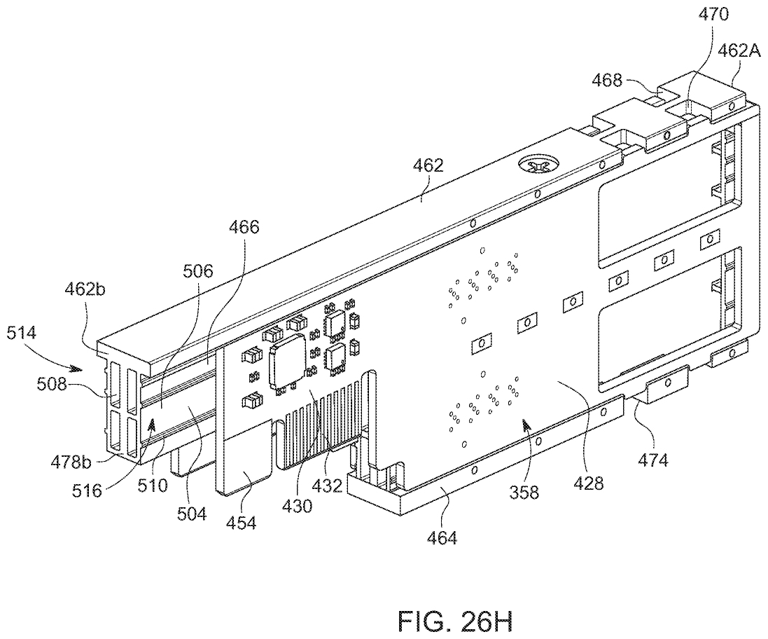

In an embodiment as shown in FIGS. 26A and 26F, the rear portion 430 of the card 358 has a block 454 formed of an insulative material which extends outwardly from each of the side surfaces 430d, 430e. Each block 454 extends from the edge on which the contact pads 432 are provided and extends from the rear edge 430c of the rear portion 430. The connectors 434 on the front circuit board 324 have an opening 456 into which the blocks 454 are accepted. The blocks 454 assist in properly orienting the card 358 and the connector 434.

To further support adjacent card assemblies mounted on the front circuit board 324, a support member 460 as shown in FIGS. 26A-26H can be provided between the adjacent card assemblies 357 to provide further rigidity to the assembly. The support member 460 is suitably secured in the box 322. The support member 460 is preferably made of a conductive material but can be made of insulative materials for easier forming and lower cost (but also with lower thermal performance). The support member 460 is described in the orientation shown in FIGS. 26A-26H for ease in description, however, when the I/O connector assemblies 320 are provided such that the contact pads 432 are on the upper edge 430b of the rear portion 430, the support member 460 would be rotated 180 degrees in use from the orientation shown in FIGS. 26A-26H.

In an embodiment, the support member 460 may generally be formed as an I-beam and has a top horizontally extending wall 462 having a front end 462a and a rear end 462b, a bottom horizontally extending wall 464 having a front end 464a and a rear end 464b, and a vertical connecting wall 466 connecting the top and bottom walls 462, 464 together.

The top wall 462 has a top surface 462c, a bottom surface 462d, a first side edge 462e extending from the front end 462a to the rear end 462b and between the top and bottom surfaces 426c, 426d, and an opposite second side edge 462f extending from the front end 462a to the rear end 462b and between the top and bottom surfaces 426c, 426d. The bottom surface 462d is planar. A plurality of notches 468 are provided in the top wall 462 and extend from the first side edge 462e. A plurality of notches 470 are provided in the top wall 462 and extend from the second side edge 462f.

The bottom wall 464 has a top surface 464c, a bottom surface 464d, a first side edge 464e extending from the front end 464a to the rear end 464b and between the top and bottom surfaces 426c, 426d, and an opposite second side edge 464f extending from the front end 464a to the rear end 464b and between the top and bottom surfaces 426c, 426d. The bottom surface 464d is planar. A plurality of notches 472 are provided in the bottom wall 464 and extend from the first side edge 464e. A plurality of notches 474 are provided in the bottom wall 464 and extend from the second side edge 464f. The top surface 464c of the bottom wall 464 faces the bottom surface 462d of the top wall 462. The bottom wall 464 is shorter in length than the top wall 462.

The vertical connecting wall 466 has a front section 476 which extends from the front ends 462a, 464a of the top and bottom walls 462, 464 to a rear section 478 which extends from the front section 476 to the rear end 462b of the top wall 462. The front section 476 extends to the rear end 464b of the bottom wall 464. The front section 476 has a front surface 476a, a rear surface 476b, a first side surface 476c extending between the front and rear surfaces 476a, 476b, and a second side surface 476d extending between the front and rear surfaces 476a, 476b. A width of the front section 476 is defined between the side surfaces 476c, 476d.

The rear section 478 has a front end 478a, a rear surface 478b, a first side surface 478c extending between the front end 478a and the rear surface 478b, a second side surface 478d extending between the front end 478a and the rear surface 478b, and a lower end surface 478e extending between the front end 478a and the rear surface 478b. A width of the rear section 478 is defined between the side surfaces 478c, 478d. A notch 480 is defined by the rear surface 476b of the front section 476 and the lower end surface 478e of the rear section 478.

A first pair of vertically spaced apart openings 482, 484 are provided through the front section 476 rearward of a front surface 476a thereof such that a first upper opening 482 is provided and a first lower opening 484 is provided which are separated by a first horizontal portion 486 of the front section 476. A second pair of vertically spaced apart openings 488, 490 are provided through the front section 476 rearward of the first pair of openings 482, 484 such that a second upper opening 488 is provided and a second lower opening 490 is provided which are separated by a second horizontal portion 492 of the front section 476. The first pair of openings are 482, 484 separated from the second pair of openings 488, 490 by a vertical portion 494 of the front section 476. A front vertical portion 496 of the front section 476 is defined forward of the openings 482, 484, and a rear vertical portion 498 of the front section 476 is defined rearward of the openings 488, 490.

The front vertical portion 496 has a width which is the same as the width of the horizontal portions 486, 492. The front vertical portion 496 has a plurality of openings 500 which extend from the front surface 476a to the openings 482, 484. The vertical portion 494 has a width which is less than front vertical portion 496 and the horizontal portions 486, 492 and is provided in the middle of the horizontal portions 486, 492. The rear vertical portion 496 has a width which is less than front vertical portion 496 and the horizontal portions 486, 492 and is offset to the second side surface 476d.

The rear section 478 has a front portion 504 which has a width which is equal to the rear vertical portion 498 and aligns with the rear vertical portion 498, and a rear portion 506 which extends from the front portion 504 and has a width which is equal to the front vertical portion 496. Openings 508 extend through the rear portion 506 from the front end thereof which is proximate to the front portion 504 to the rear surface 478b of the vertical connecting wall 466.

Horizontally extending spaced apart ribs 510 extend outwardly from the first side surfaces 476c, 478c of the rear vertical portion 496 of the front section 476 and the front portion 504 of the rear section 478. Horizontally extending spaced apart ribs 512 extend outwardly from the second side surfaces 476d, 478d of the rear vertical portion 496 of the front section 476 and the front portion 504 of the rear section 478. As such, a first pocket 514 is formed by on one side of the vertical connecting wall 466, and a second pocket 516 is formed by on the other side of the vertical connecting wall 466.

When the card assemblies 357 are attached to the support member 460, the card 358 of each card assembly 357 seats within the respective pocket 514, 516 and feet on the card 358 of each card assembly 357 seats within the notches 468, 470, 472, 474 and may engaged by a friction fit or permanently secured thereto. The card 358 seated within pocket 514 engages against the front vertical portion 496, the horizontal portions 486, 492, and the ribs 510. The card 358 seated within pocket 516 engages against the front vertical portion 496, the horizontal portions 486, 492, and the ribs 512. The card 358 of each card assembly 357 is spaced from the vertical portion 494. As a result, air can flow from the front of the support member 460 to the rear of the support member 460 between the cards 358 and the support member 460. The fins 420 seat within the pockets 514, 516 on each side of the support member 460.

As shown in FIGS. 26C and 26F, in an embodiment, a cover 518 is attached to the free end of the fins 420. The cover 518 is preferably a thermally conductive material. The cover 518 may be attached to the fins 420 by conductive adhesive. In addition, light pipes may be provided in the I/O connector assemblies 320.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

We claim:

1. A card assembly, comprising:
a card with a front portion and a rear portion and a first side and a second side and an aperture extending between the first and second sides and contact pads positioned in the rear portion;
an I/O cage assembly mounted on the first side of the card, the I/O cage assembly having a cage that defines a port with a front opening and having a receptacle connector positioned in the port and configured to engage a plug module inserted into the port, the cage including a first opening and a second opening, the first and second openings being positioned on opposite sides of the cage, the second opening being aligned with the aperture;
a first heat sink assembly positioned on the cage and having a first projection that extends into the first opening so as to extend into the port; and
a second heat sink assembly positioned on the second side of the card, the second heat sink having a second projection that extends through the aperture and the second opening so as to extend into the port.

2. The card assembly of claim 1, wherein the I/O cage assembly is a first I/O cage assembly and the aperture being a first aperture, the card having a second aperture and supporting a second I/O cage assembly aligned with the second aperture, wherein the port is a first port and the second I/O cage assembly defining a second port.

3. The card assembly of claim 2, wherein the card is configured to be aligned vertically.

4. The card assembly of claim 1, wherein the first heat sink assembly is a riding heat sink configured to engage a plug module respectively inserted into the first and second ports.

5. The card assembly of claim 1, further comprising a cable assembly extending from the I/O cage assembly, the cable assembly configured to pass high speed signal from the connector to a connector system adjacent a chip package.

6. The card assembly of claim 1, wherein the first heat sink assembly is a riding heat sink

7. A computing box, comprising:
a box with a front face;
a circuit board arranged in a horizontal manner in the box, the circuit board spaced apart from the front face, the circuit board having a board connector mounted thereon; and
a card assembly mounting to the circuit board, the card assembly comprising:
a card with a front portion and a rear portion and a first side and a second side and an aperture extending between the first and second sides and contact pads positioned in the rear portion, the contact pads engaging the board connector;
an I/O cage assembly mounted on the first side of the card, the I/O cage assembly including a cage that defines a port with a front edge and a receptacle connector positioned in the port and configured to engage a plug module inserted into the port, the front edge of cage being aligned with the front face of the box, the cage including a first opening and a second opening, the first and second openings being positioned on opposite sides of the cage, the second opening being aligned with the aperture;
a first heat sink assembly positioned on the cage and having a first projection that extends into the first opening so as to extend into the port; and
a second heat sink assembly positioned on the second side of the card, the second heat sink having a second projection that extends through the aperture and the second opening so as to extend into the port.

8. The box assembly of claim 7, wherein the board connector is configured to receive the contact pads in a vertical direction.

9. The box assembly of claim 7, wherein the connector is connector to a cable assembly, the cable assembly configured to distribute high speed signal therealong.

10. The box assembly of claim 9, wherein the cable assembly is connected to a connector assembly positioned adjacent a chip package.

11. The box assembly of claim 7, wherein the box supports a plurality of card assemblies positioned adjacent to each other, each of the card assemblies being arranged in a vertical configuration.

12. The box assembly of claim 11, wherein the front face includes a plurality of air flow openings positioned between each the openings provided by the adjacent card assemblies.
